(19) United States
(12) Patent Application Publication
(10) Pub. No.: US 2024/0320714 A1
(43) Pub. Date: Sep. 26, 2024

(54) SYSTEMS AND METHODS FOR CONTEXTUAL CONTENT GENERATION

(71) Applicant: ADOBE INC., SAN JOSE, CA (US)

(72) Inventors: Rebecca Dorothy West, Auburn, CA (US); Lauren Dest, Austin, TX (US); Mihir Naware, Redwood City, CA (US); Elliot Axel Patrick Puzenat, Le Plessis Robinson (FR); Stephen Becigneul, Levallois-Perret (FR); Alexis Tessier, Eckwersheim (FR); Roger K. Brooks, Palo Alto, CA (US); Suman Basetty, Fremont, CA (US); Kimberly K. Lenox, Orinda, CA (US); Anil Kamath, Los Altos Hills, CA (US)

(21) Appl. No.: 18/477,735

(22) Filed: Sep. 29, 2023

Related U.S. Application Data
(60) Provisional application No. 63/491,499, filed on Mar. 21, 2023.

(51) Int. Cl. G06Q 30/0241; G06F 40/40; G06Q 30/0204

(52) U.S. Cl. CPC G06Q 30/0276; G06F 40/40; G06Q 30/0204

(57) ABSTRACT

A method, non-transitory computer readable medium, apparatus, and system for contextual content generation are described. An embodiment of the present disclosure includes obtaining, by a user experience platform, a content provider context for the user experience platform. The content provider context includes profile information for a content provider and an interaction history of the content provider. The user experience platform obtains a prompt based on the content provider context. Embodiments of the present disclosure further include generating content for a project within the user experience platform based on the prompt using a machine learning model.

### CROSS-REFERENCE TO RELATED APPLICATION

This application claims the benefit, under 35 U.S.C. § 119, of the filing date of U.S. Provisional Application No. 63/491,499, filed on Mar. 21, 2023, in the United States Patent and Trademark Office. The disclosure of U.S. Provisional Application No. 63/491,499 is incorporated by reference herein in its entirety.

### BACKGROUND

The following relates generally to content generation, and more specifically to contextual content generation using machine learning. In some cases, content is generated based on meaningful information learned from data processing. Data processing refers to a collection and manipulation of data to produce the meaningful information. Machine learning is an information processing field in which algorithms or models such as artificial neural networks are trained to make predictive outputs in response to input data without being specifically programmed to do so.

In some cases, conventional content generation systems rely upon manual content provider navigation of a set of user interfaces or user interface elements, which is inefficient, time-consuming, and labor-intensive. There is therefore a need in the art for a content generation system that offers an efficient content provider experience.

### SUMMARY

Embodiments of the present disclosure provide a content generation system that obtains a context for a content provider's interaction with the content generation system, obtains a prompt for a machine learning model based on the context, and generates content based on the prompt using the machine learning model.

By obtaining the prompt based on the content provider context, the content generation system is able to use the machine learning model to output content that is appropriate for a project of the content provider within a content provider context of the content generation system.

A method, apparatus, non-transitory computer readable medium, and system for content generation are described. One or more aspects of the method, apparatus, non-transitory computer readable medium, and system include obtaining a content provider context for a user experience platform, wherein the content provider context includes profile information for a content provider and an interaction history of the content provider; obtaining a prompt based on the content provider context; and generating content for a project within the user experience platform based on the prompt using a machine learning model.

An apparatus and system for content generation are described. One or more aspects of the apparatus and system include at least one processor; at least one memory storing instructions executable by the at least one processor; a user experience platform configured to obtain a prompt based on a content provider context for a user experience platform, wherein the content provider context includes profile information for a content provider and an interaction history of the content provider; and a machine learning model including machine learning model parameters stored in the at least one memory and trained to generate content for a project within the user experience platform based on the prompt.

### BRIEF DESCRIPTION OF THE DRAWINGS

FIG. 1 shows an example of a content generation system according to aspects of the present disclosure.

FIG. 2 shows an example of a content generation apparatus according to aspects of the present disclosure.

FIG. 3 shows an example of a transformer according to aspects of the present disclosure.

FIG. 4 shows an example of data flow in a content generation system according to aspects of the present disclosure.

FIG. 5 shows an example of a method for generating content based on content provider input according to aspects of the present disclosure.

FIG. 6 shows an example of a method for content generation according to aspects of the present disclosure.

FIG. 7 shows an example of a user interface for generated insights according to aspects of the present disclosure.

FIG. 8 shows an example of a prompt element for generated insights according to aspects of the present disclosure.

FIG. 9 shows an example of a user interface for opportunities according to aspects of the present disclosure.

FIG. 10 shows an example of a user interface for a generated campaign according to aspects of the present disclosure.

FIG. 11 shows an example of a user interface for user segmentation according to aspects of the present disclosure.

FIG. 12 shows an example of a user interface for predicted user behavior according to aspects of the present disclosure.

FIG. 13 shows an example of a user interface for a modified campaign according to aspects of the present disclosure.

FIG. 14 shows an example of a user interface for an image according to aspects of the present disclosure.

FIG. 15 shows an example of a user interface for image modification according to aspects of the present disclosure.

FIG. 16 shows an example of a user interface for a modified image according to aspects of the present disclosure.

FIG. 17 shows an example of a user interface for an image according to aspects of the present disclosure.

FIG. 18 shows an example of a user interface for user journey generation according to aspects of the present disclosure.

FIG. 19 shows an example of a user interface for a user journey according to aspects of the present disclosure.

FIG. 20 shows an example of a user interface for a modification of an active content distribution campaign according to aspects of the present disclosure.

FIG. 21 shows an example of a method for training a machine learning model according to aspects of the present disclosure.

### DETAILED DESCRIPTION

In some cases, content generation for user experience strategies is informed by a wide variety of factors, including ever-changing market trends, user preferences, and signals from social, economic, and political landscapes. An ability to quickly and intelligently understand, plan for, and react to such factors greatly assists a content provider in achieving its goals.

At the same time, users are increasingly embracing digital channels to engage with content providers and are demanding that content providers personalize their interactions. Therefore, both users and content providers benefit when an intent, stage, and context of users are understood and a digital experience is tailored for the users. In some cases, a confluence of personalization at scale along with a myriad of macro influences presents an opportunity for a content generation system for digital user experience management that operates at a granularity of an individual user's journey and sequence of experiences, all while helping a content provider to achieve its goals.

However, producing an effective content distribution campaign by synthesizing external and internal data into actionable opportunities, creating superior campaign components (e.g., content, journeys, objectives, etc.), and optimizing a content distribution strategy over time is not easily achievable for a content provider team, and added challenges of a demand from content providers for new, fresh, and personalized user experiences and siloed teams balancing various overlapping efforts creates further complication for creating an effective campaign.

In some cases, conventional content generation systems rely upon manual content provider navigation of a set of user interfaces or user interface elements, which is inefficient, time-consuming, and labor-intensive.

For example, in some cases, a superior campaign draws upon vast and disparate external and internal data that individual strategists and analysts are not able to effectively comprehend or synthesize within an allotted time. In some cases, a significant part of an analyst's time is spent on retrieving basic key performance indicator (KPI) questions with little bandwidth for deep analysis, while in some cases, strategists such as campaign owners and managers rely on an ad hoc analysis of internal and external sources from analysts to come to a point solution campaign.

Furthermore, in some cases, a process of conceiving, executing, and evaluating a campaign is laborious and time-consuming and is constrained both by a number of available team members and an ability to rapidly and effectively respond to quickly moving user preferences. For example, in some cases, a conventional process for creating a campaign brief includes one or more of determining a campaign objective, a channel for content distribution, a program for content distribution, a target audience, and content to be distributed. Additionally, in some cases, an end-to-end content distribution effort is scattered across different roles, making an ability to quickly and dynamically adjust campaign components based on ever-changing trends a challenge.

For example, in some cases, strategists rely on operations teams, creative teams, and other team members to execute a point solution campaign. During such a process, in some cases, a performance-based adjustment to the campaign is time-consuming, as the adjustment demands waiting for a full cycle to re-engage team members that are now occupied with different tasks. Additionally, in some cases, a content distribution effort is hampered by a lack of healthy knowledge-sharing practices across teams, resulting in silos, inefficiencies, and bottlenecks.

Still further, in some cases, content distribution workflows are heavy, manual, and dependent upon a constant supply of human ingenuity and accuracy. For example, in some cases, operations team members that are focused on building user journeys perform numerous iterations according to an intuition of what aspects of a prospective user journey might be effective. Additionally, in some cases, creative team members have a limited capacity to create variations of content for campaigns, particularly based on historical performance and content affinity variations for clients and consumers.

Additionally, in some cases, an ability to create a tailored experience and user journey for each unique user is constrained by an ability of content provider teams to generate and deliver appropriate content at an appropriate time.

According to some aspects, a content generation system includes a user experience platform and a machine learning model. In some cases, the content generation system is configured to obtain a prompt based on a content provider context for a user experience platform. In some cases, the content provider context includes profile information for a content provider and an interaction history of the content provider. In some cases, the machine learning model includes machine learning model parameters stored in the at least one memory and is trained to generate content for a project within the user experience platform based on the prompt.

According to some aspects, by obtaining the prompt based on the content provider context, the content generation system is able to use the machine learning model to output content that is appropriate for a stage of a project of the content provider within the content generation system.

According to some aspects, the content generation system uses a user experience platform and a machine learning model to generate content based on a content provider context, thereby helping a content provider learn and reach their goals faster than by using a conventional content generation system. In some cases, a prompt element of the content generation system accepts one or more of a text content provider input and an image content provider input. In some cases, the prompt element is summoned from any user interface or user interface element provided by the content generation system. In some cases, the content generation system presents the prompt element unsummoned when there is a relevant suggestion or action to be added. In some cases, the content generation system adapts context to a specific solution or a workflow from which the prompt element was summoned. In some cases, the content generation system retains past context and conversations and considers the content provider's role, title, and position within an organization when interfacing with the content provider.

In some cases, the content generation system provides one or more of a text output and a beyond-text output, such as an image, a chart, a representation of a user journey, a representation of a campaign program, etc.

In some cases, the machine learning model is a transformer-based sequence-to-sequence model that is trained on a public corpus of information and is able to understand semantics of a natural language input. In some cases, the machine learning model is further contextualized with a content provider's specific content distribution content, such as a campaign brief, a campaign program, a user journey, etc. In some cases, the machine learning model is optimized and adjusted via one or more of implicit feedback and explicit feedback.

In some cases, therefore, when the content generation system receives a natural language input from a content provider, the content generation system provides a prompt including the natural language input and the content provider context for the natural language input to the machine learning model, and the trained machine learning model is able to understand the prompt to generate content that is relevant to the natural language input and to the content provider context.

A content generation system according to an aspect of the present disclosure is used in a user experience project creation context. In an example, a content provider is using the content generation system to work on a content distribution campaign project, where the campaign will target users who travel by themselves. The content provider is currently viewing a user interface provided by the content generation system for editing an image to be distributed to a user.

The user experience platform obtains content provider context for the content provider's present and past interactions within the user experience platform, such as profile information for the content provider (e.g., a content provider identifier, content provider preferences, etc.) and an interaction history of the content provider (for example, including data relating to previous and current steps in the content provider project, such as identifying a user segment for a content distribution campaign, identifying an objective for the content distribution campaign, and generating a campaign brief for the content distribution campaign, and the current step of editing an image identified by the campaign brief for distribution during the content distribution campaign).

In an example, the content provider summons a prompt element on the user interface by a prompt element summoning input (such as a selection of a summoning element, a keyboard input, a voice command, etc.) provided to the user interface by a content provider device. The content provider provides a text input “Make this feel more inspirational” to the prompt element.

The user experience platform obtains a prompt by generating the prompt based on the content provider context and the content provider input. The user experience platform provides the prompt to the machine learning model. The machine learning model generates content according to the prompt.

In the example, the content includes: text that is responsive to the content provider input (e.g., “Content tuning: There are a few tweaks we can make to ensure your campaign content hits the right inspirational tone”, “Lighting and atmospheric tuning: Solo Travelers are more likely to associate vivid color, sunrises, and sunsets with inspiration”, and “Subject matter tuning: Featuring group tours in visuals and messaging are likely to inspire Solo Travelers who have a propensity to purchase guided experiences”); instructions for the user experience platform to retrieve specific images corresponding to the text from a database; and instructions for the user experience platform to display the text, thumbnails of the retrieved images, and a button for “Retune my content” in a pop-up window to be displayed above the user interface for editing the image.

The user experience platform executes the instructions included in the content to display the text, the image thumbnails, and the button as specified by the content. The content provider selects one of the thumbnails and the “Retune my content” button to be brought to a new image editing user interface displaying the image corresponding to the selected thumbnail.

Accordingly, because the prompt was generated based on the content provider context, the machine learning model was able to generate content that was responsive to a content provider input in the context of the content provider input, and was therefore able to appropriately respond to a content provider input (“Make this feel more inspirational”) that would be meaningless without the content provider context.

Accordingly, in some cases, the content generation system provides a multimodal conversational interface (such as a copilot for user experience management) capable of brainstorming, ideation, and reasoning, that retains context and therefore adapts to any user interface displayed by a user experience platform.

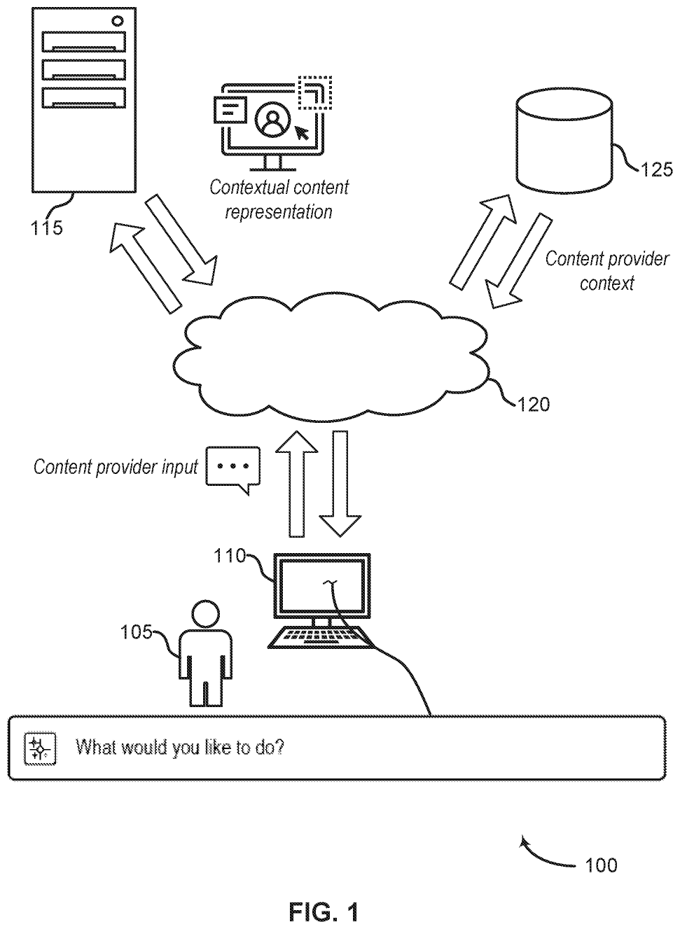

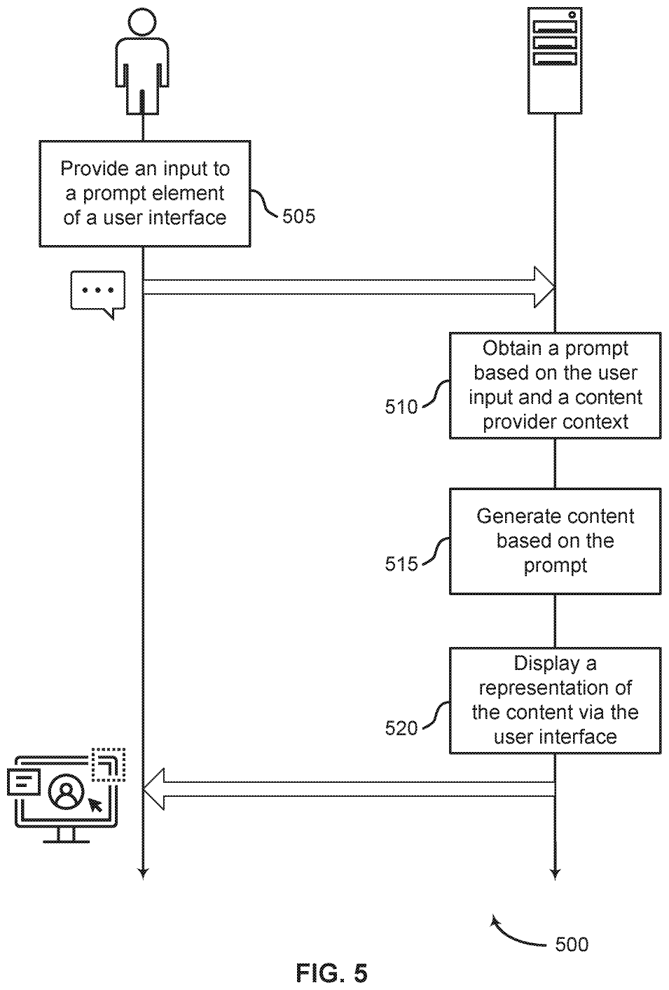

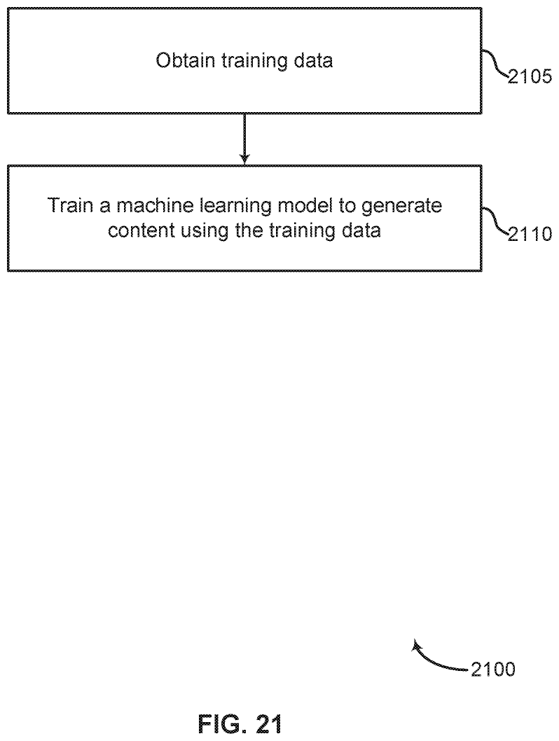

Further example applications of the present disclosure in a user experience project creation context are provided with reference to FIGS. 1 and 5. Details regarding the architecture of the content generation system are provided with reference to FIGS. 1-4. Details regarding a process for content generation are provided with reference to FIGS. 5-20. Details regarding a process for training a machine learning model are provided with reference to FIG. 21.

As used herein, in some cases, a “content provider” refers to a person or entity that interacts with the content generation system and/or content generation apparatus. As used herein, in some cases, a “content provider preference” refers to any information provided by the content provider to the content generation system. In some cases, a content provider preference includes one or more of a preferred content, a preferred communication channel, a preferred campaign objective, a preferred user segment, a preferred time period for content distribution, and any other information that is used in developing a content distribution campaign for a content provider.

As used herein, a “user segment” or “audience” refers to a group of users corresponding to a group of user profiles and identified by a group of user identifiers. As used herein, a “user profile” refers to data corresponding to a user. Examples of data corresponding to a user include a name, contact information, demographic data, user device information, a purchase history, a correspondence history, and any other data relating to the user. As used herein, a “user identifier” refers to a unique identifier (such as a name, an email address, an identification number, etc.) for a user. In some cases, a user profile includes a user identifier. In some cases, the user segment includes one or more users corresponding to user profiles that include a common attribute or quality.

As used herein, a “content provider context” refers to contextual information for a user experience platform. As used herein, a “profile information for a content provider” or a “content provider profile” refers to any available data for a content provider, such as an identifier, a title, a role within an organization, content provider preferences, etc. As used herein, an “interaction history of the content provider” refers to data relating to any interaction of the content provider with the content generation system, such as inputs provided to the content generation system, user interfaces viewed by the content provider, content provided by the content generation system for the content provider, time spent interacting with the content generation system, an active user interface element, a currently selected user interface element, information represented in a user interface element, etc.

In some cases, a content provider context includes one or more of: the profile information for a content provider; the interaction history of the content provider; information corresponding to an active user interface (such as data corresponding to information being represented by the user interface, link selection within the user interface, a mouse or other input position in the user interface, an amount of time spent in the user interface, etc.); an analytics context; an audience segmentation context; a campaign generation context; structured information representing a user journey, a campaign brief, or a campaign program; information in multiple modalities, such as a text modality or an image modality; data corresponding to a data trend or anomaly; an insight; an opportunity; content provider preferences (such as a campaign objective, a campaign goal, a preferred user segment, a preferred communication channel, preferred content, etc.); a content provider playbook; a key performance indicator; previous content provider feedback; and any other available information that is or has been presented to or retrieved by the user experience platform.

As used herein, in some cases, a “user experience platform” includes a set of creative, analytics, social, advertising, media optimization, targeting, Web experience management, journey orchestration and content management tools. In some cases, a user experience platform comprises one or more ANNs trained to generate content. In some cases, a user experience platform provides the user interface. In some cases, the user experience platform communicates with a database. In some cases, the user experience platform comprises the database.

As used herein, a “prompt” refers to an input to a machine learning model. In some cases, the prompt includes the content provider context. In some cases, the prompt includes an instruction to generate content based on the content provider context. In some cases, the prompt includes text provided by a content provider. In some cases, the prompt includes an instruction to generate the content according to one or more of the content provider context, the text provided by the content provider, and the instruction. In some cases, one or more of the text provided by the content provider and the instruction includes natural language. As used herein, “natural language” refers to any language that has emerged through natural use.

In some cases, the user experience platform generates the prompt. In some cases, the user experience platform generates the prompt in response to a content provider input to an element of a user interface. In some cases, the user experience platform generates the prompt in response to a change in the content provider context. In some cases, the content provider provides the prompt to the machine learning model (for example, via a user interface configured to communicate with the machine learning model).

In some cases, the prompt includes one or more embeddings. As used herein, an “embedding” refers to a mathematical representation of an object (such as text, an image, a chart, audio, etc.) in a lower-dimensional space, such that information about the object is more easily captured and analyzed by a machine learning model. For example, in some cases, an embedding is a numerical representation of the object in a continuous vector space in which objects that have similar semantic information correspond to vectors that are numerically similar to and thus “closer” to each other, providing for an ability of a machine learning model to effectively compare the objects corresponding to the embeddings with each other.

In some cases, an embedding is produced in a “modality” (such as a text modality, a chart modality, an image modality, an audio modality, etc.) that corresponds to a modality of the corresponding object. In some cases, embeddings in different modalities include different dimensions and characteristics, which makes a direct comparison of embeddings from different modalities difficult. In some cases, an embedding for an object is generated or translated into a multimodal embedding space, such that objects from multiple modalities are effectively comparable with each other.

As used herein, in some cases, “content” includes any form of media, including goods, services, physically tangible media, and the like, and digital content, including media such as text, audio, images, video, or a combination thereof. In some cases, content includes text, such as descriptions, summaries, insights, opportunities, structured queries, campaign briefs, user journey outlines, copy, subject headlines, hashtags, text for inclusion in an image, etc. In some cases, content includes instructions or code (such as a macro) that is executed by the user experience platform to retrieve and/or generate content, such as an image, a chart, a slide presentation, a video, audio, etc. In some cases, content includes instructions or code that is executed by the user experience platform to display content or a representation of the content via the user interface.

As used herein, in some cases, an “insight” includes a natural language description of a data trend or anomaly. In some cases, the insight includes a natural language analysis of the data trend (such as an identification of a predicted cause or contributing factor for the data trend and a prediction of an effect of the data trend). In some cases, the insight includes a text instruction provided in an appropriate format (such as an instruction, code, a macro, etc.) for a different component (such as the user experience platform) to take some action (such as retrieve, generate, and or/display content). In some cases, an insight is synthesized and curated from external and internal sources in various forms, such as data stories, charts, visuals, etc.

In some cases, the data sources are inclusive of at least one of a foundational enterprise/content distribution focus and a unique content provider-specific foundation.

Examples of data having a foundational enterprise/content distribution focus include publicly available competitor information and announcements, market research reports, brand awareness and perception data, company and industry data, demographic data, seasonal data, macroeconomic data, microeconomic data, and data relating to world events.

Examples of data having a content provider-specific foundation include user and segmentation data, content affinity data based on historical responses to content distribution campaigns, user journey preferences (such as frequency, channels, and content preferences) based on historical performance of content distribution campaigns, share partner or purchased data, historical content distribution campaign details and performance data, brand guidelines and historical content experiences, previous experiments and results, and user research, such as market research and churn analysis.

As used herein, in some cases, an “opportunity” includes a natural language description of an action for the content provider to take based on the insight. In some cases, the opportunity includes a natural language suggestion to the content provider to instruct the content generation system to take a further action (such as identifying a group of content providers, generating a content distribution campaign, etc.) based on the insight. In some cases, the opportunity includes a text instruction provided in an appropriate format (such as a programming language) for a different component (such as the user experience platform) to take an action (such as identifying the group of content providers, generating the content distribution campaign, etc.). In some cases, an opportunity is curated with consideration to one or more of a content provider's goals, playbook, active or previous campaigns, and historical performance.

As used herein, a “structured query” refers to a statement provided in a structured query language (SQL). In some cases, SQL is a programming language for storing and processing information in a database. In some cases, SQL integrates with various programming languages. In some cases, the structured query is embedded with a programming language. In some cases, the structured query includes common keywords. In some cases, a database stores information in tabular form according to SQL, with rows and columns representing different data attributes and the various relationships between the data values. In some cases, the structured query is used to store, update, remove, search, or retrieve information from the database organized according to one or more SQL tables. In some cases, a structured query includes a translation by a machine learning model of information included in or associated with a prompt into SQL.

As used herein, a “content distribution campaign”, “communication campaign”, or “campaign” refers to a coordinated distribution of content through one or more content channels in order to achieve one or more goals, such as a number of product purchases, a number of content views, a number of sign-ups, etc.

In some cases, a content distribution campaign is planned according to a campaign brief. As used herein, a “campaign brief” refers to text including a description of one or more components or elements of a content distribution campaign, such as an identification of one or more of content to be distributed, an identification of a user segment for receiving the distributed content, a channel for distributing the content through, and a period (either stage-based or calendar-based) for distributing the content. As used herein, “stage-based” refers to periods determined according to an order of occurrence. As used herein, “calendar-based” refers to periods determined according to calendar dates.

In some cases, a campaign brief defines aspects of a campaign, including one or more of a target audience, a key performance indicator (KPI), an objective for the campaign, a timeframe for providing content according to the campaign, personnel assignments, campaign budget information, and content associated with the campaign. In some cases, the campaign brief is a roadmap for a content provider to execute on and a source of truth for the campaign.

In some cases, the campaign brief identifies a plurality of stages and a program for each of the set of periods. As used herein, in some cases, a “program” refers to a plotted timeline of content distribution according to the set of periods. In some cases, the communication channel is associated with the program for at least one of the set of periods.

In some cases, the campaign brief includes a description of a user journey. As used herein, in some cases, a “user journey” refers to a process through which a user becomes aware of and interacts with the content provider or a client of the content provider. In some cases, the user journey includes a set of planned touchpoints in which content is provided to the user. In some cases, a touchpoint of the set of planned touchpoints is planned according to one or more of a period of time, an interaction of the user with a content channel (such as a visit to a physical location or a digital content channel such as a social media feed), or an occurrence of a previous touchpoint.

In some cases, the campaign brief includes a set of content elements. In some cases, the set of content elements includes at least one text element and at least one visual element. In some cases, the campaign brief includes a summary of the content distribution campaign corresponding to the campaign brief. In some cases, the summary comprises a natural language statement. In some cases, the campaign brief includes a title or a label for the content distribution campaign.

In some cases, a content distribution campaign package includes one or more of a campaign brief, a user segment, a generated content experience, a user journey, a simulation of a user journey, and a prediction of a result of a user journey. In some cases, the campaign brief is generated based on one or more of the content provider's goals, a playbook, active or previous campaigns, and a historical performance. In some cases, a user segment is generated based on one or more of a campaign focus, a campaign goal, a historical affinity, and a historical performance. In some cases, a content experience is generated based on a composition of individual content pieces, such as images, copy, video, audio, subject headlines, hashtags, etc. In some cases, a user journey is generated, simulated, and/or predicted based on one or more of a historical user journey, results of a historical user journey, and industry standards derived from external data. In some cases, the content distribution campaign package is dynamically optimized and adjusted based on generated insights of emerging external or internal trends. In some cases, the content distribution campaign package is dynamically optimized and adjusted based on feedback loops from the content distribution campaign, where the feedback is provided by one or more of the content provider and a user targeted by the content distribution campaign.

As used herein, a “communication channel” or a “content distribution channel” refers to a physical channel (such as a mailing service, a physical location such as a store, a hotel, an amusement park, etc., and the like) or a digital channel (such as a website, a software application, an Internet-based application, an email service, a messaging service such as SMS, instant messaging, etc., a television service, a telephone service, etc.) through which content or digital content is provided. As used herein, “customized content” refers to content that is customized according to data associated with a content provider or a user.

As used herein, in some cases, a “project” refers to a process of using the content generation system to produce an output or outcome.

While in some cases, conventional content generation systems rely upon manual content provider navigation of a set of user interfaces or user interface elements, which is inefficient, time-consuming, and labor intensive, a content generation system according to some aspects obtains a prompt based on a content provider context and generates content based on the prompt. By obtaining the prompt based on the content provider context, the content generation system is able to use the machine learning model to output content that is appropriate for a project of the content provider within the content generation system. In some cases, the content provider therefore avoids a manual user interface navigation while working on the project. Furthermore, in some cases, the generated content is predictive of a next step in the project or offers suggested actions, thereby helping the content provider to brainstorm and ideate for the project.

Furthermore, unlike conventional content generation systems which use employ generative machine learning, according to some aspects, the content generation system goes beyond image and text generation to deliver insights and opportunities to a content provider to create a content distribution package in addition to text and image content, such as harmonious multimodal experiences and performant content that leverages content insights from user's data and content. According to some aspects, the content generation system includes a comprehensive user experience management suite for planning, execution, and analysis to execute personalization-at-scale strategies. According to some aspects, the content generation system integrates workflows for experience creation and delivery so that there is no need for a content provider to employ another system.

According to some aspects, the content generation system assists with an ideation, definition, expansion, and refinement of an audience for the content distribution campaign. For example, in some cases, the machine learning model qualifies and quantifies the audience using summary statistics and described traits of the audience along with projected performance of the audience towards the content distribution objective of the content provider.

According to some aspects, the content generation system employs at least one of the user experience platform and the machine learning model to generate a complete content distribution campaign, including a program, messaging, content, and journey, or a combination thereof. For example, in some cases, the content generation system optimizes the content distribution campaign for a target audience to meet the content distribution objective of the content provider.

According to some aspects, the content generation system infuses capabilities of the machine learning model with capabilities of the user experience cloud to provide a multimodal conversational interface capable of brainstorming, ideation, and reasoning, that retains and adapts to context. In some cases, the conversational interface is implemented as a copilot for user experience management.

According to some aspects, the content generation system is directed by additional inputs and/or dimensions to dynamically and continuously regenerate generated outputs. According to some aspects, journeys, journey simulation, and performance predictions are based on historical journey data of a content provider combined with external journey data leveraged by the machine learning model.

Accordingly, in some cases, the content generation system provides a content provider with efficiency, efficacy, scale, agility, velocity, ideation, collaboration, and/or execution, thereby allowing the content provider to do more with less.

### Content Generation System

A system and an apparatus for content generation are described with reference to FIGS. 1-4. One or more aspects of the system and the apparatus include at least one processor; at least one memory storing instructions executable by the at least one processor; a user experience platform configured to obtain a prompt based on a content provider context for a user experience platform, wherein the content provider context includes profile information for a content provider and an interaction history of the content provider; and a machine learning model including machine learning model parameters stored in the at least one memory and trained to generate content for a project within the user experience platform based on the prompt.

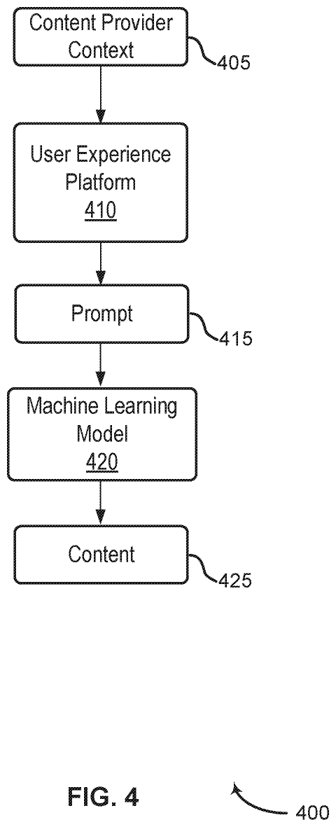

FIG. 1 shows an example of a content generation system 100 according to aspects of the present disclosure. The example shown includes content provider 105, content provider device 110, content generation apparatus 115, cloud 120, and database 125. Content generation system 100 is an example of, or includes aspects of, the corresponding element described with reference to FIG. 4.

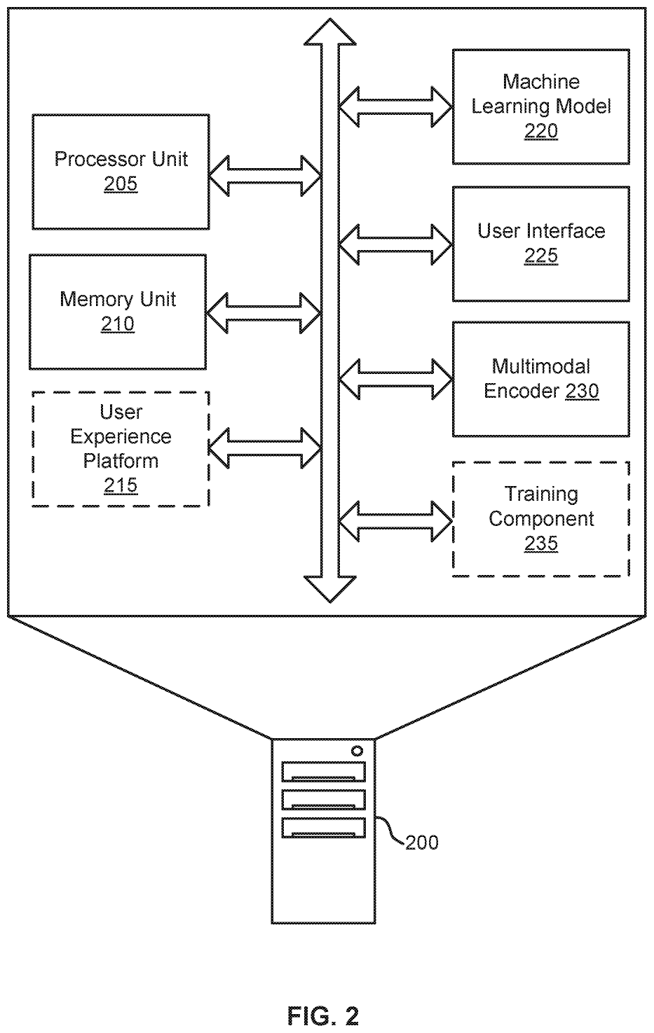

In an example shown by FIG. 1, content generation apparatus 115 obtains a content provider context for content provider 105, including profile information for content provider 105 and an interaction history of content provider 105, from database 125. Content generation apparatus 115 provides a prompt element (for example, displaying the text “What would you like to do?”) to content provider 105 on content provider device 110 via a user interface (such as the user interface described with reference to FIGS. 2 and 7-20). Content provider 105 provides a content provider input (e.g., a text input or an image input) to the prompt element.

Content generation apparatus 115 obtains a prompt based on the content provider context and the content provider input and generates content based on the prompt. Content generation apparatus 115 displays a representation of the content to content provider 105 via the user interface.

Content provider device 110 is an example of, or includes aspects of, the corresponding element described with reference to FIG. 4. According to some aspects, content provider device 110 is a personal computer, laptop computer, mainframe computer, palmtop computer, personal assistant, mobile device, or any other suitable processing apparatus. In some examples, content provider device 110 includes software that displays the user interface (e.g., the graphical user interface) provided by content generation apparatus 115. In some aspects, the user interface allows information (such as text, an image, etc.) to be communicated between content provider 105 and content generation apparatus 115.

According to some aspects, a content provider device user interface enables content provider 105 to interact with content provider device 110. In some embodiments, the content provider device user interface includes an audio device, such as an external speaker system, an external display device such as a display screen, or an input device (e.g., a remote-control device interfaced with the user interface directly or through an I/O controller module). In some cases, the content provider device user interface is a graphical user interface.

Content generation apparatus 115 is an example of, or includes aspects of, the corresponding element described with reference to FIG. 2. According to some aspects, content generation apparatus 115 includes a computer-implemented network. In some embodiments, the computer-implemented network includes a machine learning model (such as the machine learning model described with reference to FIGS. 2 and 4). In some embodiments, content generation apparatus 115 also includes one or more processors, a memory subsystem, a communication interface, an I/O interface, one or more user interface components, and a bus. Additionally, in some embodiments, content generation apparatus 115 communicates with content provider device 110 and database 125 via cloud 120.

In some cases, content generation apparatus 115 is implemented on a server. A server provides one or more functions to content providers linked by way of one or more of various networks, such as cloud 120. In some cases, the server includes a single microprocessor board, which includes a microprocessor responsible for controlling all aspects of the server. In some cases, the server uses microprocessor and protocols to exchange data with other devices or content providers on one or more of the networks via one or more of hypertext transfer protocol (HTTP), simple mail transfer protocol (SMTP), file transfer protocol (FTP), and simple network management protocol (SNMP). In some cases, the server is configured to send and receive hypertext markup language (HTML) formatted files (e.g., for displaying web pages). In various embodiments, the server comprises a general-purpose computing device, a personal computer, a laptop computer, a mainframe computer, a supercomputer, or any other suitable processing apparatus.

Further detail regarding the architecture of content generation apparatus 115 is provided with reference to FIGS. 2-4. Further detail regarding a process for content generation is provided with reference to FIGS. 5-20. Further detail regarding a process for training a machine learning model is provided with reference to FIG. 21.

Cloud 120 is a computer network configured to provide on-demand availability of computer system resources, such as data storage and computing power. In some examples, cloud 120 provides resources without active management by a content provider. The term “cloud” is sometimes used to describe data centers available to many content providers over the Internet.

Some large cloud networks have functions distributed over multiple locations from central servers. A server is designated an edge server if it has a direct or close connection to a content provider. In some cases, cloud 120 is limited to a single organization. In other examples, cloud 120 is available to many organizations.

In one example, cloud 120 includes a multi-layer communications network comprising multiple edge routers and core routers. In another example, cloud 120 is based on a local collection of switches in a single physical location. According to some aspects, cloud 120 provides communications between content provider device 110, content generation apparatus 115, and database 125.

Database 125 is an example of, or includes aspects of, the corresponding element described with reference to FIG. 4. Database 125 is an organized collection of data. In an example, database 125 stores data in a specified format known as a schema. According to some aspects, database 125 is structured as a single database, a distributed database, multiple distributed databases, or an emergency backup database. In some cases, a database controller manages data storage and processing in database 125 via manual interaction or automatically without manual interaction. According to some aspects, database 125 is external to content generation apparatus 115 and communicates with content generation apparatus 115 via cloud 120. According to some aspects, database 125 is included in content generation apparatus 115. According to some aspects, database 125 stores a content provider context. According to some aspects, database 125 stores at least some of the content provider context.

FIG. 2 shows an example of a content generation apparatus 200 according to aspects of the present disclosure. Content generation apparatus 200 is an example of, or includes aspects of, the corresponding element described with reference to FIG. 1. In one aspect, content generation apparatus 200 includes processor unit 205, memory unit 210, user experience platform 215, machine learning model 220, user interface 225, multimodal encoder 230, and training component 235.

Processor unit 205 includes one or more processors. A processor is an intelligent hardware device, such as a general-purpose processing component, a digital signal processor (DSP), a central processing unit (CPU), a graphics processing unit (GPU), a microcontroller, an application specific integrated circuit (ASIC), a field programmable gate array (FPGA), a programmable logic device, a discrete gate or transistor logic component, a discrete hardware component, or any combination thereof.

In some cases, processor unit 205 is configured to operate a memory array using a memory controller. In other cases, a memory controller is integrated into processor unit 205. In some cases, processor unit 205 is configured to execute computer-readable instructions stored in memory unit 210 to perform various functions. In some aspects, processor unit 205 includes special purpose components for modem processing, baseband processing, digital signal processing, or transmission processing.

Memory unit 210 includes one or more memory devices. Examples of a memory device include random access memory (RAM), read-only memory (ROM), or a hard disk. Examples of memory devices include solid state memory and a hard disk drive. In some examples, memory is used to store computer-readable, computer-executable software including instructions that, when executed, cause at least one processor of processor unit 205 to perform various functions described herein.

In some cases, memory unit 210 includes a basic input/output system (BIOS) that controls basic hardware or software operations, such as an interaction with peripheral components or devices. In some cases, memory unit 210 includes a memory controller that operates memory cells of memory unit 210. For example, in some cases, the memory controller includes a row decoder, column decoder, or both. In some cases, memory cells within memory unit 210 store information in the form of a logical state.

User experience platform 215 is an example of, or includes aspects of, the corresponding element described with reference to FIG. 4. According to some aspects, user experience platform 215 is implemented as software stored in memory unit 210 and executable by processor unit 205, as firmware, as one or more hardware circuits, or as a combination thereof.

According to some aspects, user experience platform 215 is omitted from content generation apparatus 200 and is implemented in at least one apparatus separate from content generation apparatus 200 (for example, at least one apparatus comprised in a cloud, such as the cloud described with reference to FIG. 1). According to some aspects, the separate apparatus comprising user experience platform 215 communicates with content generation apparatus 200 (for example, via the cloud) to perform the functions of user experience platform 215 described herein.

For example, in some cases, content generation apparatus 200 is implemented as an edge server in a content generation system (such as the content generation system described with reference to FIGS. 1 and 4), user experience platform 215 is included in a central server of the content generation system, and content generation apparatus 200 communicates with the central server to implement the functions of user experience platform 215 described herein.

According to some aspects, user experience platform 215 includes a set of creative, analytics, social, advertising, media optimization, targeting, Web experience management, journey orchestration and content management tools. In some cases, user experience platform 215 includes one or more of a graphic design component providing image generation and/or editing capabilities, a video editing component, a web development component, and a photography component.

In some cases, user experience platform 215 comprises one or more of an enterprise content management component; a digital asset management component; an enterprise content distribution component that manages direct content distribution campaigns, leads, resources, user data, and analytics, and allows content providers to design and orchestrate targeted and personalized campaigns via channels such as direct mail, e-mail, SMS, and MMS; a data management component for data modeling and predictive analytics; and a web analytics system that provides web metrics, dimensions, and allows content provider to define tags implemented in webpage for web tracking to provide customized dimensions, metrics, segmentations, content provider reports, and dashboards.

In some cases, user experience platform 215 has comprehensive end-to-end capabilities with content distribution-specific technology across conceptualization, execution, and insights to merge with machine learning model 220 and generative machine learning experiences. In some cases, user experience platform 215 builds a cohesive user view, supporting but not limited to analytics, digital advertising, email, user data management, social media, call centers, and commerce. In some cases, user experience platform 215 consolidates, identifies, and builds full profiles from datasets that provide differentiating data for generating content that benefits from personalization.

According to some aspects, user experience platform 215 comprises one or more ANNs, and one or more components of user experience platform 215 are implemented via the one or more ANNs. In some cases, user experience platform 215 comprises one or more generative machine learning models configured to generate content.

According to some aspects, user experience platform 215 obtains a content provider context for a user experience platform 215, where the content provider context includes profile information for a content provider and an interaction history of the content provider. In some aspects, the content provider context includes information in multiple modalities including a text modality and an image modality. In some examples, the content provider context comprises a user journey, analytics context, an audience segmentation context, a campaign generation context, or any combination thereof. In some example, the content provider context includes structured information representing a user journey, a campaign brief, or a campaign program.

In some examples, user experience platform 215 obtains a prompt based on the content provider context. In some examples, user experience platform 215 receives a content provider input via the prompt element, where the prompt is based on the content provider input. In some examples, user experience platform 215 generates the prompt based on the content provider context.

In some examples, user experience platform 215 provides a recommendation to the content provider for an interaction with the user experience platform. In some cases, user experience platform 215 receives a request from a content provider to generate the content.

In some examples, user experience platform 215 receives feedback from the content provider based on the content. In some examples, user experience platform 215 updates machine learning model 220 based on the feedback.

Machine learning model 220 is an example of, or includes aspects of, the corresponding element described with reference to FIG. 4. According to some aspects, machine learning model 220 is implemented as software stored in memory unit 210 and executable by processor unit 205, as firmware, as one or more hardware circuits, or as a combination thereof. In some cases, machine learning model 220 is included in user experience platform 215. According to some aspects, machine learning model 220 comprises one or more artificial neural networks (ANNs) designed and/or trained to generate content based on a prompt.

An ANN is a hardware component or a software component that includes a number of connected nodes (i.e., artificial neurons) that loosely correspond to the neurons in a human brain. Each connection, or edge, transmits a signal from one node to another (like the physical synapses in a brain). When a node receives a signal, it processes the signal and then transmits the processed signal to other connected nodes.

In some cases, the signals between nodes comprise real numbers, and the output of each node is computed by a function of the sum of its inputs. In some examples, nodes determine their output using other mathematical algorithms, such as selecting the max from the inputs as the output, or any other suitable algorithm for activating the node. Each node and edge are associated with one or more node weights that determine how the signal is processed and transmitted.

In ANNs, a hidden (or intermediate) layer includes hidden nodes and is located between an input layer and an output layer. Hidden layers perform nonlinear transformations of inputs entered into the network. Each hidden layer is trained to produce a defined output that contributes to a joint output of the output layer of the ANN. Hidden representations are machine-readable data representations of an input that are learned from hidden layers of the ANN and are produced by the output layer. As the understanding of the ANN of the input improves as the ANN is trained, the hidden representation is progressively differentiated from earlier iterations.

During a training process of an ANN, the node weights are adjusted to improve the accuracy of the result (i.e., by minimizing a loss which corresponds in some way to the difference between the current result and the target result). The weight of an edge increases or decreases the strength of the signal transmitted between nodes. In some cases, nodes have a threshold below which a signal is not transmitted at all. In some examples, the nodes are aggregated into layers. Different layers perform different transformations on their inputs. The initial layer is known as the input layer and the last layer is known as the output layer. In some cases, signals traverse certain layers multiple times.

According to some aspects, machine learning model 220 includes machine learning parameters stored in memory unit 210. Machine learning parameters are variables that provide a behavior and characteristics of a machine learning model. In some cases, machine learning parameters are learned or estimated from training data and are used to make predictions or perform tasks based on learned patterns and relationships in the data.

In some cases, machine learning parameters are adjusted during a training process to minimize a loss function or to maximize a performance metric. The goal of the training process is to find optimal values for the parameters that allow the machine learning model to make accurate predictions or perform well on a given task.

For example, during the training process, an algorithm adjusts machine learning parameters to minimize an error or loss between predicted outputs and actual targets according to optimization techniques like gradient descent, stochastic gradient descent, or other optimization algorithms. Once the machine learning parameters are learned from the training data, the machine learning parameters are used to make predictions on new, unseen data.

In some cases, parameters of an ANN include weights and biases associated with each neuron in the ANN that control a strength of connections between neurons and influence the ability of the ANN to capture complex patterns in data.

According to some aspects, machine learning model 220 comprises a large language model. A large language model is a machine learning model that is designed and/or trained to learn statistical patterns and structures of human language. Large language models are capable of a wide range of language-related tasks such as text completion, question answering, translation, summarization, and creative writing, in response to a prompt. In some cases, the term “large” refers to a size and complexity of the large language model, usually measured in terms of a number of parameters of the large language model, where more parameters allow a large language model to understand more intricate language patterns and generate more nuanced and coherent text.

In some cases, the large language model comprises a sequence-to-sequence (seq2seq) model. A seq2seq model comprises one or more ANNs configured to transform a given sequence of elements, such as a sequence of words in a sentence, into another sequence using sequence transformation.

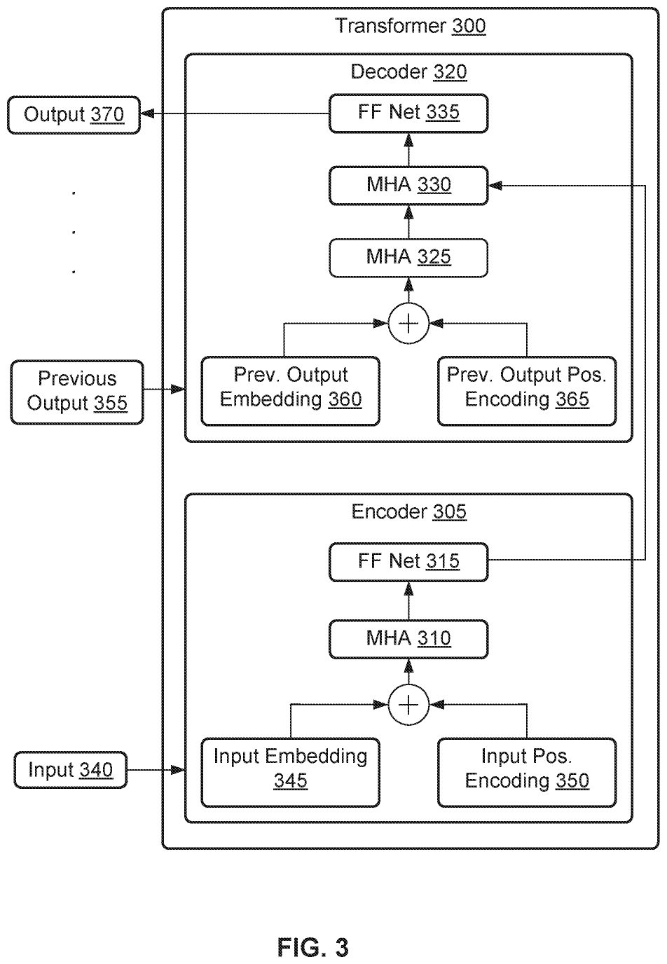

In some cases, machine learning model 220 comprises one or more transformers (such as the transformer described with reference to FIG. 3). In some cases, a transformer comprises one or more ANNs comprising attention mechanisms that enable the transformer to weigh an importance of different words or tokens within a sequence. In some cases, a transformer processes entire sequences simultaneously in parallel, making the transformer highly efficient and allowing the transformer to capture long-range dependencies more effectively.

In some cases, a transformer comprises an encoder-decoder structure. In some cases, the encoder of the transformer processes an input sequence and encodes the input sequence into a set of high-dimensional representations. In some cases, the decoder of the transformer generates an output sequence based on the encoded representations and previously generated tokens. In some cases, the encoder and the decoder are composed of multiple layers of self-attention mechanisms and feed-forward ANNs.

In some cases, the self-attention mechanism allows the transformer to focus on different parts of an input sequence while computing representations for the input sequence. In some cases, the self-attention mechanism captures relationships between words of a sequence by assigning attention weights to each word based on a relevance to other words in the sequence, thereby enabling the transformer to model dependencies regardless of a distance between words.

An attention mechanism is a key component in some ANN architectures, particularly ANNs employed in natural language processing (NLP) and sequence-to-sequence tasks, that allows an ANN to focus on different parts of an input sequence when making predictions or generating output.

NLP refers to techniques for using computers to interpret or generate natural language. In some cases, NLP tasks involve assigning annotation data such as grammatical information to words or phrases within a natural language expression. Different classes of machine-learning algorithms have been applied to NLP tasks. Some algorithms, such as decision trees, utilize hard if-then rules. Other systems use neural networks or statistical models which make soft, probabilistic decisions based on attaching real-valued weights to input features. In some cases, these models express the relative probability of multiple answers.

Some sequence models (such as recurrent neural networks) process an input sequence sequentially, maintaining an internal hidden state that captures information from previous steps. However, in some cases, this sequential processing leads to difficulties in capturing long-range dependencies or attending to specific parts of the input sequence.

The attention mechanism addresses these difficulties by enabling an ANN to selectively focus on different parts of an input sequence, assigning varying degrees of importance or attention to each part. The attention mechanism achieves the selective focus by considering a relevance of each input element with respect to a current state of the ANN.

In some cases, an ANN employing an attention mechanism receives an input sequence and maintains its current state, which represents an understanding or context. For each element in the input sequence, the attention mechanism computes an attention score that indicates the importance or relevance of that element given the current state. The attention scores are transformed into attention weights through a normalization process, such as applying a softmax function. The attention weights represent the contribution of each input element to the overall attention. The attention weights are used to compute a weighted sum of the input elements, resulting in a context vector. The context vector represents the attended information or the part of the input sequence that the ANN considers most relevant for the current step. The context vector is combined with the current state of the ANN, providing additional information and influencing subsequent predictions or decisions of the ANN.

In some cases, by incorporating an attention mechanism, an ANN dynamically allocates attention to different parts of the input sequence, allowing the ANN to focus on relevant information and capture dependencies across longer distances.

In some cases, calculating attention involves three basic steps. First, a similarity between a query vector Q and a key vector K obtained from the input is computed to generate attention weights. In some cases, similarity functions used for this process include dot product, splice, detector, and the like. Next, a softmax function is used to normalize the attention weights. Finally, the attention weights are weighed together with their corresponding values V. In the context of an attention network, the key K and value V are typically vectors or matrices that are used to represent the input data. The key K is used to determine which parts of the input the attention mechanism should focus on, while the value V is used to represent the actual data being processed.

According to some aspects, machine learning model 220 generates content for a project within the user experience platform 215 based on the prompt. In some examples, the content is generated based on the information in the multiple modalities. In some examples, the content is generated in response to the request. In some cases, the recommendation is based on the content.

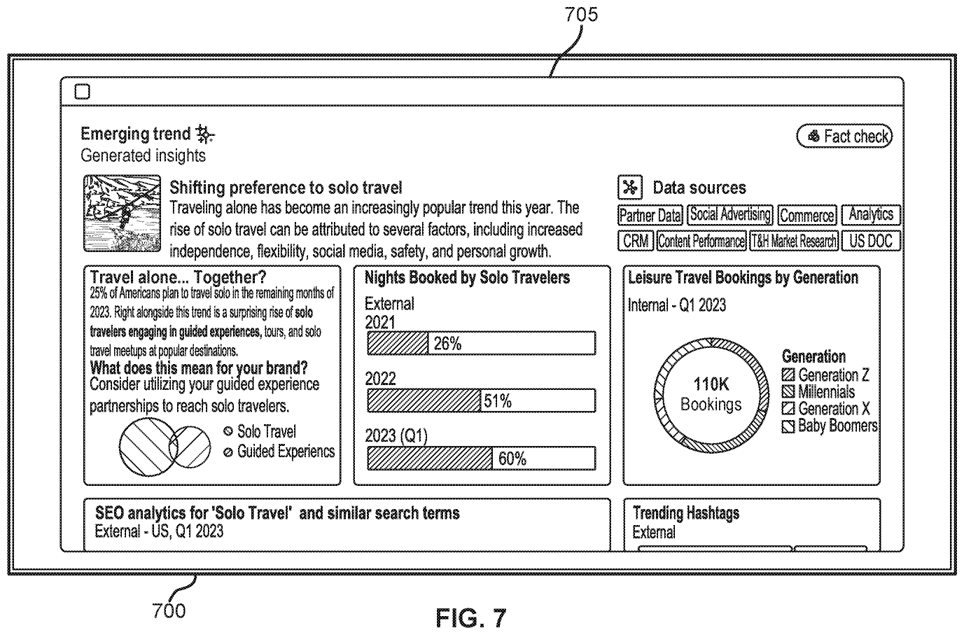

User interface 225 is an example of, or includes aspects of, the corresponding element described with reference to FIGS. 7-20. According to some aspects, user interface 225 provides for communication between a content provider device (such as the content provider device described with reference to FIG. 1) and content generation apparatus 200. For example, in some cases, user interface 225 is a graphical user interface (GUI) provided on the content provider device by content generation apparatus 200. According to some aspects, user interface 225 displays a prompt element based on the interaction history. According to some aspects, user interface 225 displays a representation of content. According to some aspects, user interface 225 receives a content provider input.

According to some aspects, multimodal encoder 230 is implemented as software stored in memory unit 210 and executable by processor unit 205, as firmware, as one or more hardware circuits, or as a combination thereof. According to some aspects, multimodal encoder 230 comprises one or more ANNs designed and/or trained to generate an embedding for an input. According to some aspects, multimodal encoder 230 comprises multimodal encoder parameters stored in memory unit 210.

According to some aspects, multimodal encoder 230 comprises a text encoder comprising one or more ANNs (such as a recurrent neural network or a transformer) that are designed and/or trained to generate a text embedding in a text embedding space or a multimodal embedding space based on a text input.

A recurrent neural network (RNN) is a class of ANN in which connections between nodes form a directed graph along an ordered (i.e., a temporal) sequence. This enables an RNN to model temporally dynamic behavior such as predicting what element should come next in a sequence. Thus, an RNN is suitable for tasks that involve ordered sequences such as text recognition (where words are ordered in a sentence). In some cases, an RNN includes a finite impulse recurrent network (characterized by nodes forming a directed acyclic graph) or an infinite impulse recurrent network (characterized by nodes forming a directed cyclic graph).

According to some aspects, multimodal encoder 230 comprises an image encoder comprising one or more ANNs (such as a convolution neural network or a transformer) configured to generate an image embedding in an image embedding space or the multimodal embedding space based on an image input.

A convolution neural network (CNN) is a class of ANN that is commonly used in computer vision or image classification systems. In some cases, a CNN enables processing of digital images with minimal pre-processing. In some cases, a CNN is characterized by the use of convolutional (or cross-correlational) hidden layers. These layers apply a convolution operation to the input before signaling the result to the next layer. In some cases, each convolutional node processes data for a limited field of input (i.e., the receptive field). In some cases, during a forward pass of the CNN, filters at each layer are convolved across the input volume, computing the dot product between the filter and the input. In some cases, during a training process, the filters are modified so that they activate when they detect a particular feature within the input.

According to some aspects, multimodal encoder 230 comprises a multimodal encoder comprising one or more ANNs (such as a CLIP model) configured to generate an embedding in a multimodal embedding space based on an input, such as text or an image.

Contrastive Language-Image Pre-Training (CLIP) is an ANN architecture that is trained to efficiently learn visual concepts from natural language supervision. In some cases, CLIP is instructed in natural language to perform a variety of classification benchmarks without directly optimizing for the benchmarks' performance, in a manner building on “zero-shot” or zero-data learning. In some cases, CLIP learns from unfiltered, highly varied, and highly noisy data, such as text paired with images found across the Internet, in a similar but more efficient manner to zero-shot learning, thus reducing the need for expensive and large labeled datasets.

In some cases, a CLIP model is applicable to nearly arbitrary visual classification tasks so that the model predicts the likelihood of a text description being paired with a particular image, removing the need for content providers to design their own classifiers and the need for task-specific training data. For example, in some cases, a CLIP model is applied to a new task by inputting names of the task's visual concepts to the model's text encoder. The model then outputs a linear classifier of CLIP's visual representations.

According to some aspects, multimodal encoder 230 encodes a content provider input to a prompt element to obtain a content provider input embedding in a multimodal embedding space. According to some aspects, multimodal encoder 230 encodes a prompt to obtain a prompt embedding in a multimodal embedding space.

According to some aspects, training component 235 is implemented as software stored in memory unit 210 and executable by processor unit 205, as firmware, as one or more hardware circuits, or as a combination thereof. According to some aspects, training component 235 is omitted from content generation apparatus 200 and is implemented in at least one apparatus separate from content generation apparatus 200 (for example, at least one apparatus comprised in a cloud, such as the cloud described with reference to FIG. 1). According to some aspects, the separate apparatus comprising training component 235 communicates with content generation apparatus 200 (for example, via the cloud) to perform the functions of training component 235 described herein.

In some aspects, training component 235 trains machine learning model 220 based on a public corpus of natural language documents and fine-tuned based on data from the user experience platform 215.

FIG. 3 shows an example of a transformer 300 according to aspects of the present disclosure. The example shown includes transformer 300, encoder 305, decoder 320, input 340, input embedding 345, input positional encoding 350, previous output 355, previous output embedding 360, previous output positional encoding 365, and output 370.

In some cases, encoder 305 includes multi-head self-attention sublayer 310 and feed-forward network sublayer 315. In some cases, decoder 320 includes first multi-head self-attention sublayer 325, second multi-head self-attention sublayer 330, and feed-forward network sublayer 335.

According to some aspects, a machine learning model (such as the machine learning model described with reference to FIGS. 2 and 4) comprises transformer 300. In some cases, encoder 305 is configured to map input 340 (for example, a sequence of words or tokens, such as a prompt as described herein) to a sequence of continuous representations that are fed into decoder 320. In some cases, decoder 320 generates output 370 (e.g., a predicted sequence of words or tokens) based on the output of encoder 305 and previous output 355 (e.g., a previously predicted output sequence), which allows for the use of autoregression.

For example, in some cases, encoder 305 parses input 340 into tokens and vectorizes the parsed tokens to obtain input embedding 345, and adds input positional encoding 350 (e.g., positional encoding vectors for input 340 of a same dimension as input embedding 345) to input embedding 345. In some cases, input positional encoding 350 includes information about relative positions of words or tokens in input 340.

In some cases, encoder 305 comprises one or more encoding layers (e.g., six encoding layers) that generate contextualized token representations, where each representation corresponds to a token that combines information from other input tokens via self-attention mechanism. In some cases, each encoding layer of encoder 305 comprises a multi-head self-attention sublayer (e.g., multi-head self-attention sublayer 310). In some cases, the multi-head self-attention sublayer implements a multi-head self-attention mechanism that receives different linearly projected versions of queries, keys, and values to produce outputs in parallel. In some cases, each encoding layer of encoder 305 also includes a fully connected feed-forward network sublayer (e.g., feed-forward network sublayer 315) comprising two linear transformations surrounding a Rectified Linear Unit (ReLU) activation:

$$\\ \begin{matrix}FFN ( x ) = ReLU ( {W}_{1} x + {b}_{1} ) {W}_{2} + {b}_{2} & ( 1 )\end{matrix}$$

In some cases, each layer employs different weight parameters (W₁, W₂) and different bias parameters (b₁, b₂) to apply a same linear transformation each word or token in input 340.

In some cases, each sublayer of encoder 305 is followed by a normalization layer that normalizes a sum computed between a sublayer input x and an output sublayer(x) generated by the sublayer:

$$\\ \begin{matrix}layernorm ( x + sublayer ( x ) ) & ( 2 )\end{matrix}$$

In some cases, encoder 305 is bidirectional because encoder 305 attends to each word or token in input 340 regardless of a position of the word or token in input 340.

In some cases, decoder 320 comprises one or more decoding layers (e.g., six decoding layers). In some cases, each decoding layer comprises three sublayers including a first multi-head self-attention sublayer (e.g., first multi-head self-attention sublayer 325), a second multi-head self-attention sublayer (e.g., second multi-head self-attention sublayer 330), and a feed-forward network sublayer (e.g., feed-forward network sublayer 335). In some cases, each sublayer of decoder 320 is followed by a normalization layer that normalizes a sum computed between a sublayer input x and an output sublayer(x) generated by the sublayer.

In some cases, decoder 320 generates previous output embedding 360 of previous output 355 and adds previous output positional encoding 365 (e.g., position information for words or tokens in previous output 355) to previous output embedding 360. In some cases, each first multi-head self-attention sublayer receives the combination of previous output embedding 360 and previous output positional encoding 365 and applies a multi-head self-attention mechanism to the combination. In some cases, for each word in an input sequence, each first multi-head self-attention sublayer of decoder 320 attends only to words preceding the word in the sequence, and so transformer 300's prediction for a word at a particular position only depends on known outputs for a word that came before the word in the sequence. For example, in some cases, each first multi-head self-attention sublayer implements multiple single-attention functions in parallel by introducing a mask over values produced by the scaled multiplication of matrices Q and K by suppressing matrix values that would otherwise correspond to disallowed connections.

In some cases, each second multi-head self-attention sublayer implements a multi-head self-attention mechanism similar to the multi-head self-attention mechanism implemented in each multi-head self-attention sublayer of encoder 305 by receiving a query Q from a previous sublayer of decoder 320 and a key K and a value V from the output of encoder 305, allowing decoder 320 to attend to each word in the input 340.

In some cases, each feed-forward network sublayer implements a fully connected feed-forward network similar to feed-forward network sublayer 315. In some cases, the feed-forward network sublayers are followed by a linear transformation and a softmax to generate a prediction of output 370 (e.g., a prediction of a next word or token in a sequence of words or tokens). Accordingly, in some cases, transformer 300 generates content as described herein based on a predicted sequence of words or tokens.

FIG. 4 shows an example of data flow in a content generation system 400 according to aspects of the present disclosure. The example shown includes content generation system 400, content provider context 405, user experience platform 410, prompt 415, machine learning model 420, and content 425. Content generation system 400 is an example of, or includes aspects of, the corresponding element described with reference to FIG. 1. User experience platform 410 is an example of, or includes aspects of, the corresponding element described with reference to FIG. 2. Machine learning model 420 is an example of, or includes aspects of, the corresponding element described with reference to FIG. 2.

Referring to FIG. 4, according to some aspects, user experience platform 410 obtains content provider context 405 (for example, in response to a content provider input or to a detection of content provider context 405). In some cases, user experience platform obtains prompt 415 based on content provider context 405. In some cases, user experience platform provides prompt 415 to machine learning model 420. In some cases, machine learning model 420 generates content 425 based on prompt 415.

### Content Generation

A method for content generation is described with reference to FIGS. 5-20. One or more aspects of the method include obtaining a content provider context for a user experience platform, wherein the content provider context includes profile information for a content provider and an interaction history of the content provider; obtaining a prompt based on the content provider context; and generating content for a project within the user experience platform based on the prompt using a machine learning model. Some examples of the method further include generating the prompt based on the content provider context.

Some examples of the method further include displaying a prompt element based on the interaction history. Some examples further include receiving a content provider input via the prompt element, wherein the prompt is based on the content provider input.

In some aspects, the content provider context includes information in multiple modalities including a text modality and an image modality, wherein the content is generated based on the information in the multiple modalities. In some aspects, the content provider context comprises a user journey, analytics context, an audience segmentation context, a campaign generation context, or any combination thereof. In some aspects, the content provider context includes structured information representing a user journey, a campaign brief, or a campaign program.

Some examples of the method further include providing a recommendation to the content provider for an interaction with the user experience platform, wherein the recommendation is based on the content. Some examples of the method further include receiving a request from a content provider to generate the content, wherein the content is generated in response to the request.

Some examples of the method further include receiving feedback from the content provider based on the content. Some examples further include updating the machine learning model based on the feedback. In some aspects, the machine learning model is trained based on a public corpus of natural language documents and fine-tuned based on data from the user experience platform.

FIG. 5 shows an example of a method 500 for generating content based on content provider input according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

Referring to FIG. 5, a content generation system according to an aspect of the present disclosure is used in a user experience project creation context. In an example, a content provider provides an input to a prompt element displayed by a user interface (such as the user interface described with reference to FIGS. 2 and 7-20). The user experience platform obtains a prompt by generating the prompt based on the content provider context and the content provider input. The user experience platform provides the prompt to the machine learning model. The machine learning model generates content according to the prompt. Accordingly, because the prompt was generated based on the content provider context, the machine learning model was able to generate content that was responsive to a content provider input in the context of the content provider input.

Accordingly, in some cases, the content generation system provides a multimodal conversational interface (such as a copilot for user experience management) capable of brainstorming, ideation and reasoning, that retains context and therefore adapts to any user interface displayed by a user experience platform.

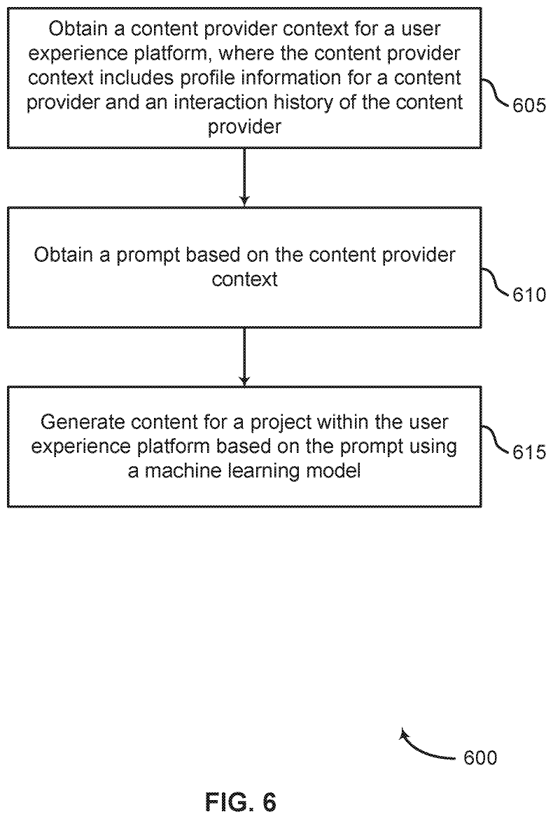

At operation 505, the system provides a content provider input to a prompt element of a user interface. In some cases, the operations of this step refer to, or are performed by, a content provider as described with reference to FIG. 1. For example, in some cases, the content provider provides the content provider input to the prompt element as described with reference to FIG. 6.

At operation 510, the system obtains a prompt based on the content provider input and a content provider context. In some cases, the operations of this step refer to, or are performed by, a content generation apparatus as described with reference to FIGS. 1 and 2. For example, a user experience platform (such as the user experience platform described with reference to FIGS. 2 and 4) obtains the content provider context and the prompt as described with reference to FIG. 6.

At operation 515, the system generates content based on the prompt. In some cases, the operations of this step refer to, or are performed by, a content generation apparatus as described with reference to FIGS. 1 and 2. For example, in some cases, the content generation apparatus generates the content using a machine learning model (such as the machine learning model described with reference to FIGS. 2 and 4) as described with reference to FIG. 6.

At operation 520, the system displays a representation of the content via the user interface. In some cases, the operations of this step refer to, or are performed by, a content generation apparatus as described with reference to FIGS. 1 and 2. For example, in some cases, the user experience platform displays a representation of a portion of the content (such as one or more of text, images, video, audio, etc., or a combination thereof, such as a chart or a representation of a campaign program or a user journey) via the user interface according to instructions included in the content.

FIG. 6 shows an example of a method 600 for content generation according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

According to some aspects, the content generation system uses a user experience platform and a machine learning model to generate content based on a content provider context, thereby helping a content provider learn and reach their goals faster than by using a conventional content generation system.

In some cases, a prompt element of the content generation system accepts one or more of a text content provider input and an image content provider input. In some cases, the prompt element is summoned from any user interface or user interface element provided by the content generation system. In some cases, the content generation system presents the prompt element unsummoned when there is a relevant suggestion or action to be added. In some cases, the content generation system adapts context to a specific solution or a workflow from which the prompt element was summoned. In some cases, the content generation system retains past context and conversations and considers the content provider's role, title, and position within an organization when interfacing with the content provider.

In some cases, the content generation system provides one or more of a text output and a beyond-text output, such as an image, a chart, a representation of a user journey, a representation of a campaign program, etc.

In some cases, the machine learning model is a transformer-based sequence-to-sequence model that is trained on a public corpus of information and is able to understand semantics of a natural language input. In some cases, the machine learning model is further contextualized with a content provider's specific content distribution content, such as a campaign brief, a campaign program, a user journey, etc. In some cases, the machine learning model is optimized and adjusted via one or more of implicit feedback and explicit feedback.

In some cases, therefore, when the content generation system receives a natural language input from a content provider, the content generation system provides a prompt including the natural language input and the content provider context for the natural language input to the machine learning model, and the trained machine learning model is able to understand the prompt to generate content that is relevant to the natural language input and to the content provider context.

At operation 605, the system obtains a content provider context for a user experience platform, where the content provider context includes profile information for a content provider and an interaction history of the content provider. In some cases, the operations of this step refer to, or are performed by, a user experience platform as described with reference to FIGS. 2 and 4.

For example, in some cases, the user experience platform obtains at least a portion of the content provider context from a database (such as a database described with reference to FIG. 1) or from another data source (such as the memory unit described with reference to FIG. 2 or another local or external memory in communication with the user experience platform). In some cases, at least a portion of the content provider context is data included in the user experience platform.

In some aspects, the content provider context includes information in multiple modalities including a text modality and an image modality. In some aspects, the content provider context comprises a user journey, analytics context, an audience segmentation context, a campaign generation context, or any combination thereof. In some aspects, the content provider context includes structured information representing a user journey, a campaign brief, or a campaign program.

In some cases, the user experience platform obtains the context in response to a change in a previous content provider context (such as a display of a new user interface element, a change in a content provider interaction with a user interface such as the user interface described with reference to FIGS. 2 and 7-20, an amount of time elapsed since the previous content provider context was obtained, a change in the content provider profile, etc.). In some cases, the user experience platform obtains the content provider context in response to a content provider input to a user interface element displayed by the user interface. In some cases, the content provider context includes data corresponding to information represented by the user interface element (such as data corresponding to a detected data trend or anomaly, an insight, an opportunity, a user segment, a content distribution campaign, a user journey, a suggested action, etc.).

In some cases, the user experience platform displays a prompt element via the user interface based on the interaction history. In some cases, the content generation apparatus displays the prompt element unsummoned. For example, in some cases, the content generation system monitors data corresponding to the content provider context, and displays the prompt element when new data is detected (such as a change in information displayed by a user interface) or when a predetermined prompt element trigger occurs (such as a change in a mouse position to an element of the user interface, an amount of time is spent viewing one user interface, a user interface element is selected, etc.). In some cases, the content generation apparatus displays the prompt element after the prompt element is summoned by a prompt element summoning content provider input (such as a selection of a summoning element displayed by the user interface, a keyboard shortcut input, a touchscreen swipe, an audio command provided by a microphone, etc.).

In some cases, the user experience platform receives a content provider input via the prompt element. In some cases, the content provider input to the prompt element is a text input (for example, a request to generate content). In some cases, the content provider input to the prompt element is an image input. In some cases, a multimodal encoder (such as the multimodal encoder described with reference to FIG. 2) receives the content provider input to the prompt element and generates a content provider input embedding in a multimodal embedding space based on the content provider input.

At operation 610, the system obtains a prompt based on the content provider context. In some cases, the operations of this step refer to, or are performed by, a user experience platform as described with reference to FIGS. 2 and 4.

For example, in some cases, the user experience platform generates the prompt based on the content provider context. In some cases, the user experience platform generates the prompt by including the content provider context in the prompt. In some cases, the user experience platform generates the prompt based on the content provider input to the prompt element. For example, in some cases, the user experience platform includes the content provider input to the prompt element or the content provider input embedding in the prompt. In some cases, the multimodal encoder encodes the prompt to obtain a prompt embedding in the multimodal embedding space.

At operation 615, the system generates content for a project within the user experience platform based on the prompt using a machine learning model. In some cases, the operations of this step refer to, or are performed by, a machine learning model as described with reference to FIGS. 2 and 4. For example, in some cases, the machine learning model receives the prompt or the prompt embedding as input. In some cases, the machine learning model includes a large language model trained to generate the content based on the prompt or the prompt embedding. In some cases, the machine learning model includes a transformer trained to generate the content based on the prompt or the prompt embedding. In some cases, the content is generated based on the information in the multiple modalities. For example, in some cases, the machine learning model generates the content based on the prompt embedding in the multimodal embedding space.

In some cases, the user experience platform retrieves and/or generates additional content based on an instruction included in the content. In some cases, the user experience platform displays the content, a representation of the content, the additional content, a representation of the additional content, or any combination thereof via the user interface (for example, in response to one or more instructions included in the content).

In some cases, the user experience platform provides a recommendation to the content provider for an interaction with the user experience platform, where the recommendation is based on the content. For example, in some cases, the content includes the recommendation, and the user experience platform displays the recommendation in response to executing an instruction included in the content to display the recommendation.

In some cases, the user experience platform receives feedback from the content provider based on the content. For example, in some cases, a content provider provides an input to a user interface element, such as a prompt element or other user interface element, in response to content displayed on the user interface. In some cases, in response to the feedback, the user experience platform generates an additional prompt based on one or more of the feedback and content provider context corresponding to the feedback. In some cases, the user experience platform updates the machine learning model by providing the additional prompt to the machine learning model. In some cases, the machine learning model generates additional content based on the additional prompt.

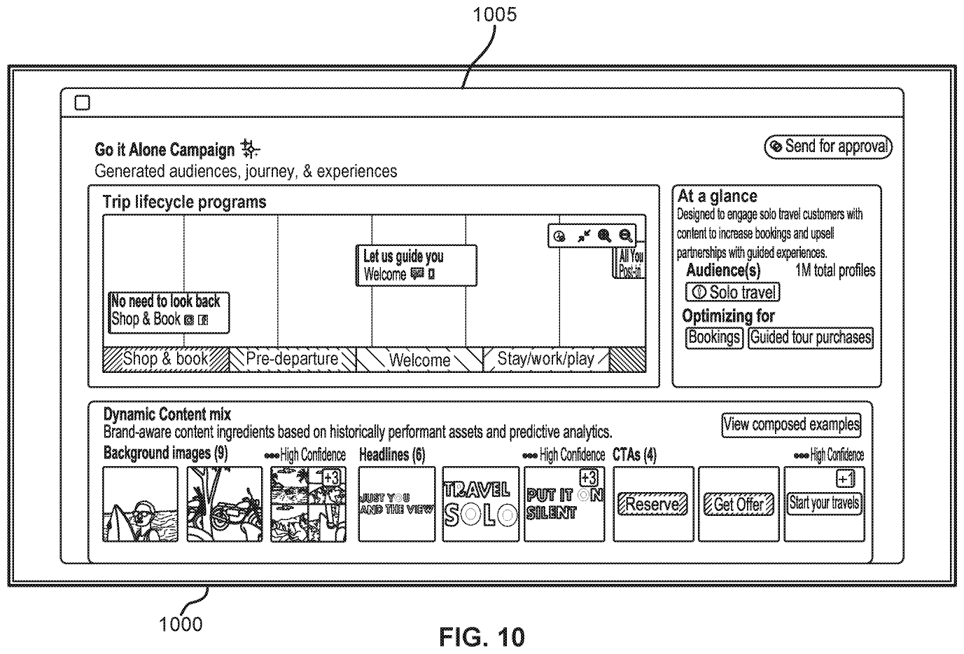

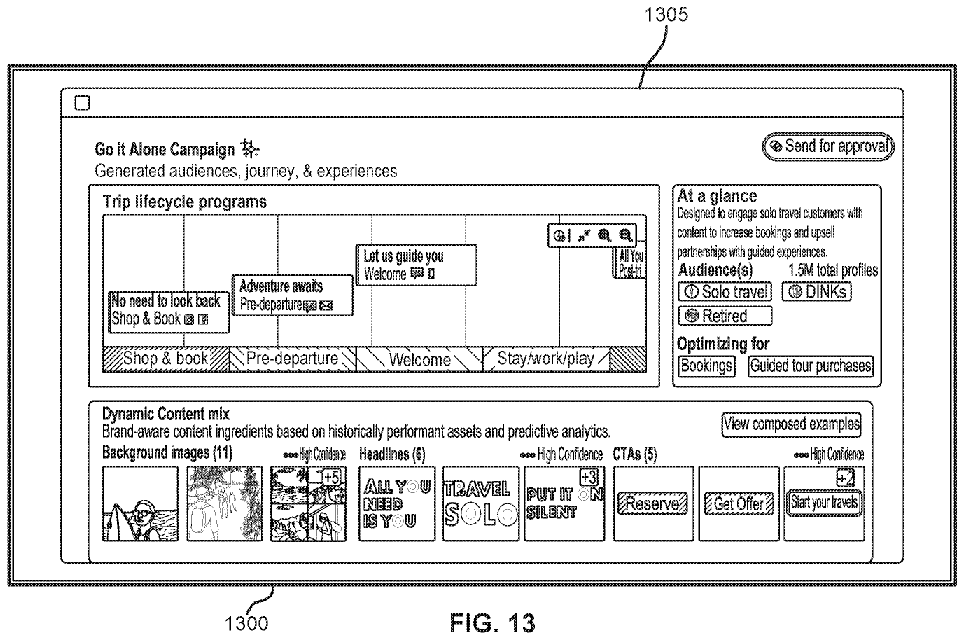

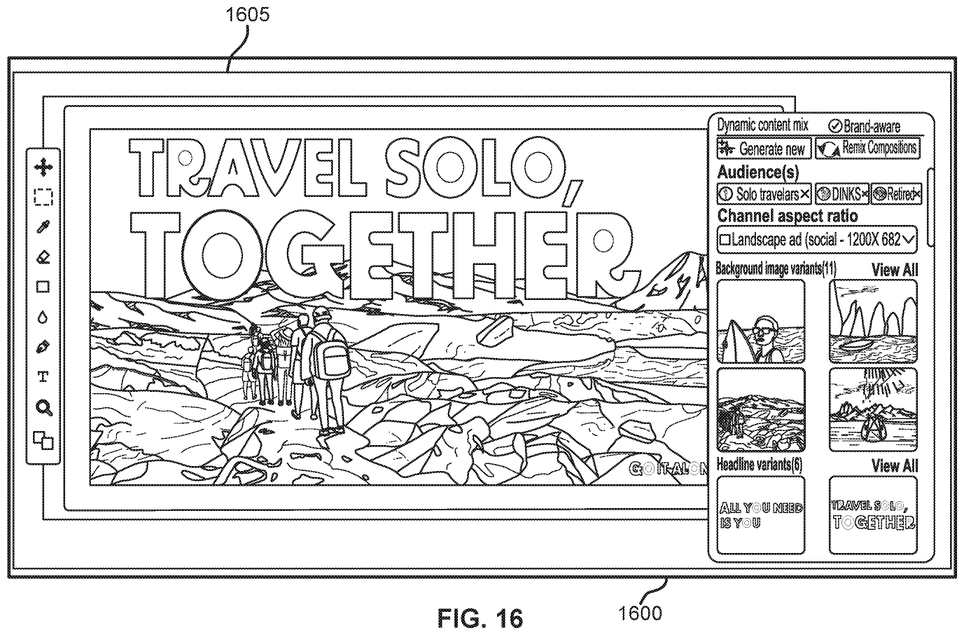

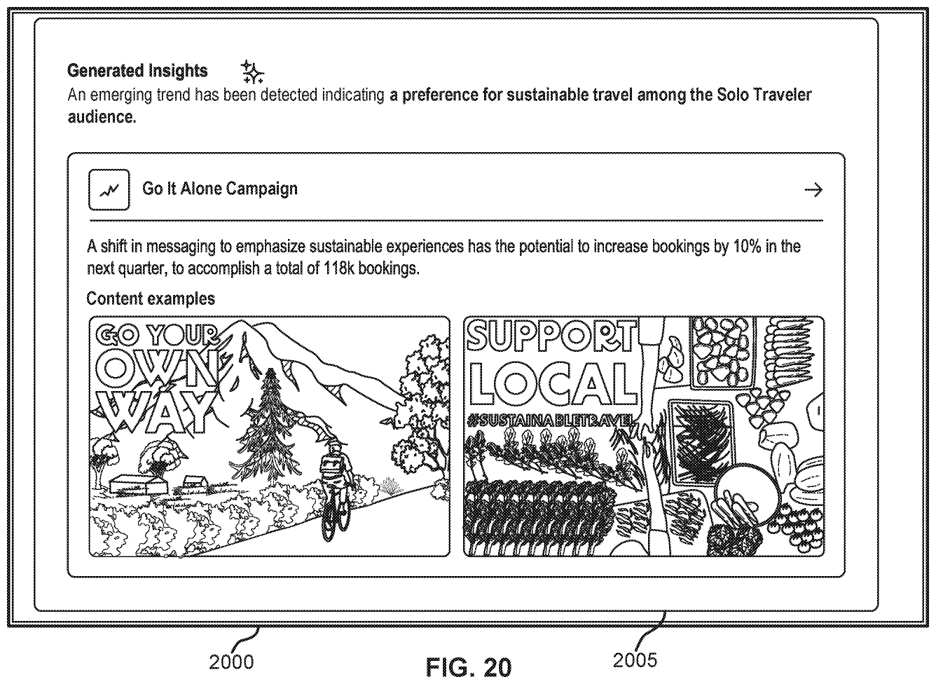

Examples of user interfaces for contextual content generation are described with reference to FIGS. 7-20. FIGS. 7-10 show examples of user interfaces for contextual content distribution campaign generation according to aspects of the present disclosure. FIGS. 10-13 show examples of user interfaces for contextual content distribution campaign modification according to aspects of the present disclosure. FIGS. 13-16 show examples of user interfaces for contextual image modification according to aspects of the present disclosure. FIGS. 16-19 show examples of contextual user journey generation according to aspects of the present disclosure. FIG. 20 shows an example of contextual modification of an active content distribution campaign according to aspects of the present disclosure.

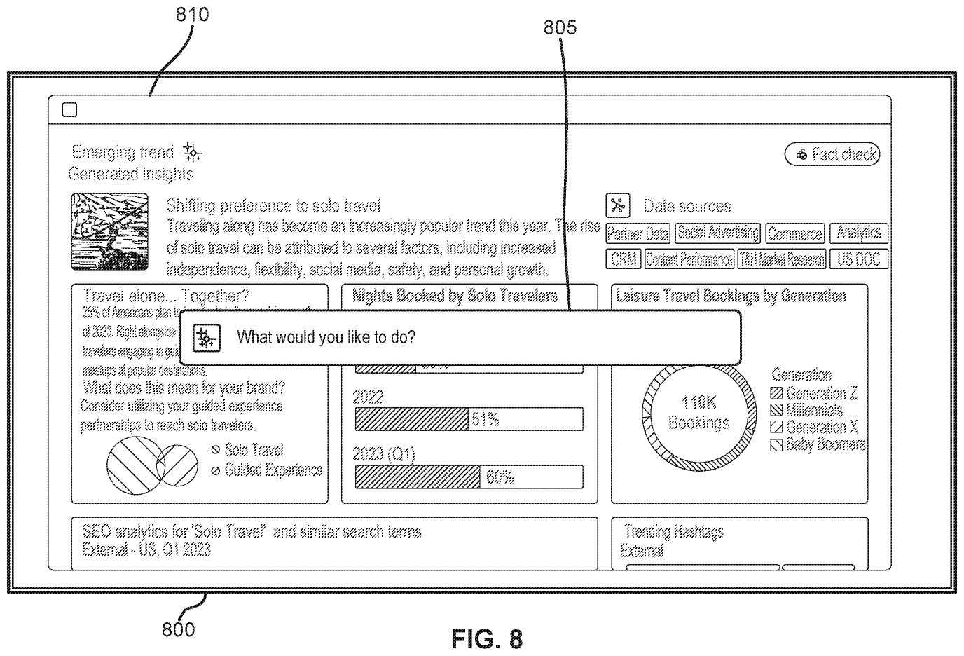

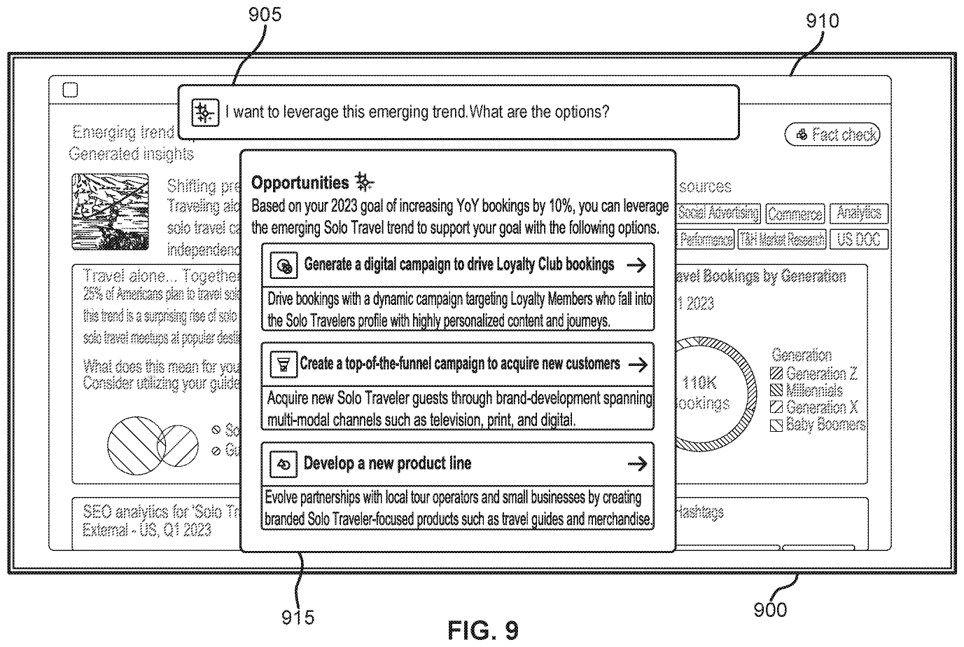

FIG. 7 shows an example of a user interface 700 for generated insights according to aspects of the present disclosure. User interface 700 is an example of, or includes aspects of, the corresponding element described with reference to FIGS. 2, and 8-20. In one aspect, user interface 700 includes first content provider context element 705. First content provider context element 705 is an example of, or includes aspects of, the corresponding element described with reference to FIGS. 8 and 9.

FIG. 8 shows an example of a prompt element 805 for generated insights according to aspects of the present disclosure. User interface 800 is an example of, or includes aspects of, the corresponding element described with reference to FIGS. 2, 7, and 9-20. In one aspect, user interface 800 includes prompt element 805 and first content provider context element 810. Prompt element 805 is an example of, or includes aspects of, the corresponding element described with reference to FIGS. 9, 11, 12, 14, 15, 17, and 18. First content provider context element 810 is an example of, or includes aspects of, the corresponding element described with reference to FIGS. 7 and 9.

FIG. 9 shows an example of a user interface 900 for opportunities according to aspects of the present disclosure. User interface 900 is an example of, or includes aspects of, the corresponding element described with reference to FIGS. 2, 7, 8, and 10-20. In one aspect, user interface 900 includes prompt element 905, first content provider context element 910, and second content provider context element 915. Prompt element 905 is an example of, or includes aspects of, the corresponding element described with reference to FIGS. 8, 11, 12, 14, 15, 17, and 18. First content provider context element 910 is an example of, or includes aspects of, the corresponding element described with reference to FIGS. 7 and 8.

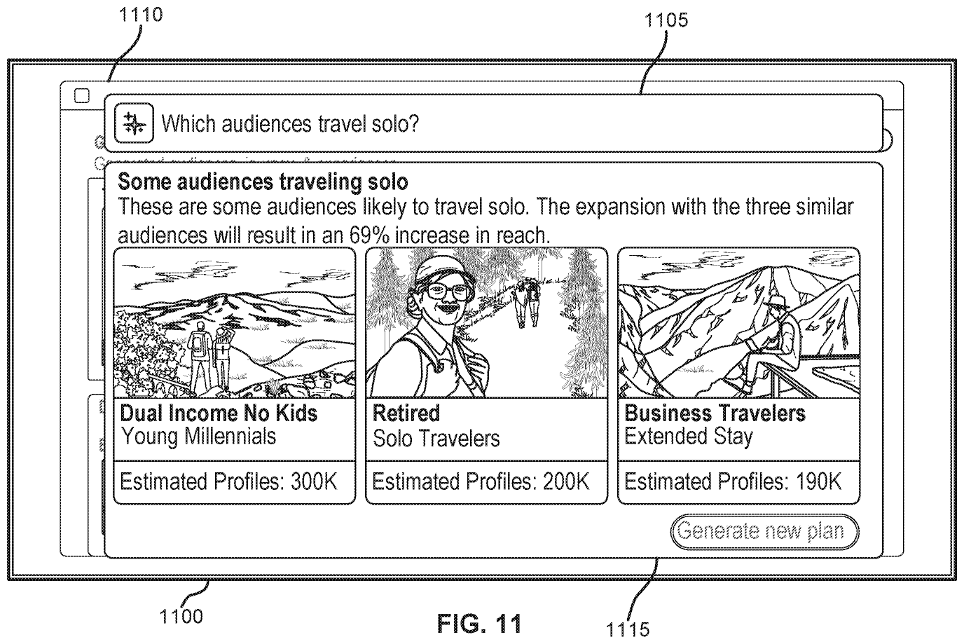

FIG. 10 shows an example of a user interface 1000 for a generated campaign according to aspects of the present disclosure. User interface 1000 is an example of, or includes aspects of, the corresponding element described with reference to FIGS. 2, 7-9, and 11-20. In one aspect, user interface 1000 includes third content provider context element 1005. Third content provider context element 1005 is an example of, or includes aspects of, the corresponding element described with reference to FIGS. 11-13.

Referring to FIGS. 7-10, a content provider uses a content generation system (such as the content generation system described with reference to FIGS. 1 and 4) to generate a content distribution campaign project. For example, as shown in FIG. 7, user interface 700 displays first content provider context element 705 corresponding to a set of insights for an emerging data trend. As shown in FIG. 8, user interface 800 displays prompt element 805 on top of a backgrounded first content provider context element 810. As shown in FIG. 9, a content provider provides a natural language input “I want to leverage this emerging trend. What are the options?” to prompt element 905 displayed by user interface 900 on top of the backgrounded first content provider context element 810.

In response to a prompt generated based on the content provider context and the content provider input provided to prompt element 905, user interface 900 displays second content provider context element 915 including a representation of opportunities generated based on the prompt. As shown in FIG. 10, user interface 1000 displays third content provider context 1005. Referring to FIGS. 9 and 10, third content provider context 1005 includes a representation of a content distribution campaign generated based on a selection of an opportunity represented in second content provider context element 915.

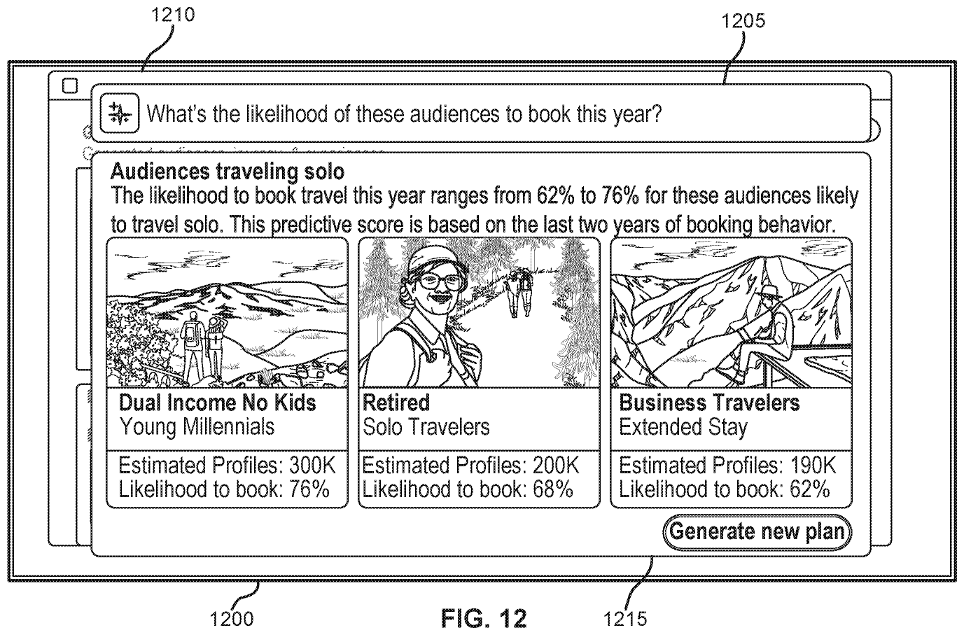

FIG. 11 shows an example of a user interface 1100 for user segmentation according to aspects of the present disclosure. User interface 1100 is an example of, or includes aspects of, the corresponding element described with reference to FIGS. 2, 7-10, and 12-20. In one aspect, user interface 1100 includes prompt element 1105, third content provider context element 1110, and fourth content provider context element 1115. Prompt element 1105 is an example of, or includes aspects of, the corresponding element described with reference to FIGS. 8, 9, 12, 14, 15, 17, and 18. Third content provider context element 1110 is an example of, or includes aspects of, the corresponding element described with reference to FIGS. 10, 12, and 13. Fourth content provider context element 1115 is an example of, or includes aspects of, the corresponding element described with reference to FIG. 12.

FIG. 12 shows an example of a user interface 1200 for predicted user behavior according to aspects of the present disclosure. User interface 1200 is an example of, or includes aspects of, the corresponding element described with reference to FIGS. 2, 7-11, and 13-20. In one aspect, user interface 1200 includes prompt element 1205, third content provider context element 1210, and fourth content provider context element 1215. Prompt element 1205 is an example of, or includes aspects of, the corresponding element described with reference to FIGS. 8, 9, 11, 14, 15, 17, and 18. Third content provider context element 1210 is an example of, or includes aspects of, the corresponding element described with reference to FIGS. 10, 11, and 13. Fourth content provider context element 1215 is an example of, or includes aspects of, the corresponding element described with reference to FIG. 11.

FIG. 13 shows an example of a user interface 1300 for a modified campaign according to aspects of the present disclosure. User interface 1300 is an example of, or includes aspects of, the corresponding element described with reference to FIGS. 2, 7-12, and 14-20. In one aspect, user interface 1300 includes third content provider context element 1305. Third content provider context element 1305 is an example of, or includes aspects of, the corresponding element described with reference to FIGS. 10-12.

Referring to FIGS. 10-13, a content provider uses a content generation system (such as the content generation system described with reference to FIGS. 1 and 4) to modify a content distribution campaign project. For example, as shown in FIG. 10, user interface 1000 displays third content provider context element 1005 including a representation of a content distribution campaign. As shown in FIG. 11, user interface 1100 displays prompt element 1105 on top of a backgrounded third content provider context element 1110, where prompt element 1105 includes a content provider input “Which audience travel solo?”. User interface 1100 displays fourth content provider context element 1115 including a representation of content corresponding to user segments based on the content provider input to prompt element 1105 and the content provider context.

As shown in FIG. 12, a content provider provides a content provider input “What's the likelihood of these audiences to book this year?” to prompt element 1205 displayed by user interface 1200 above the backgrounded third content provider context element 1210. Fourth content provider context element 1215 is updated to include content indicating a likelihood of user segments to book travel based on the content provider input to prompt element 1205 and the content provider context. Referring to FIGS. 12 and 13, user interface 1300 displays a modified third content provider context element 1305 including a modified Trip lifecycle program and Dynamic Context mix based on a content provider selection of the Generate new plan button included in fourth content provider context element 1215.

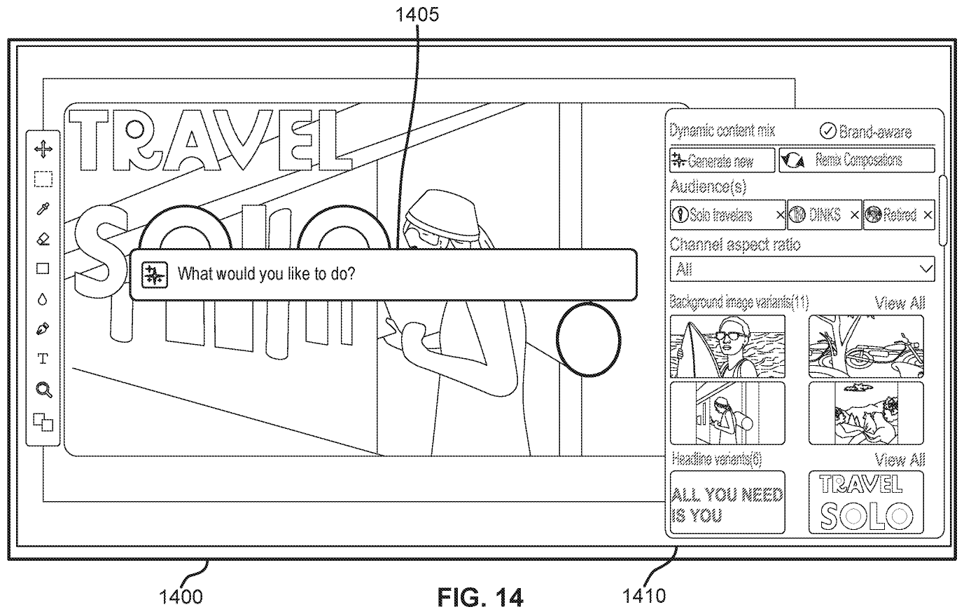

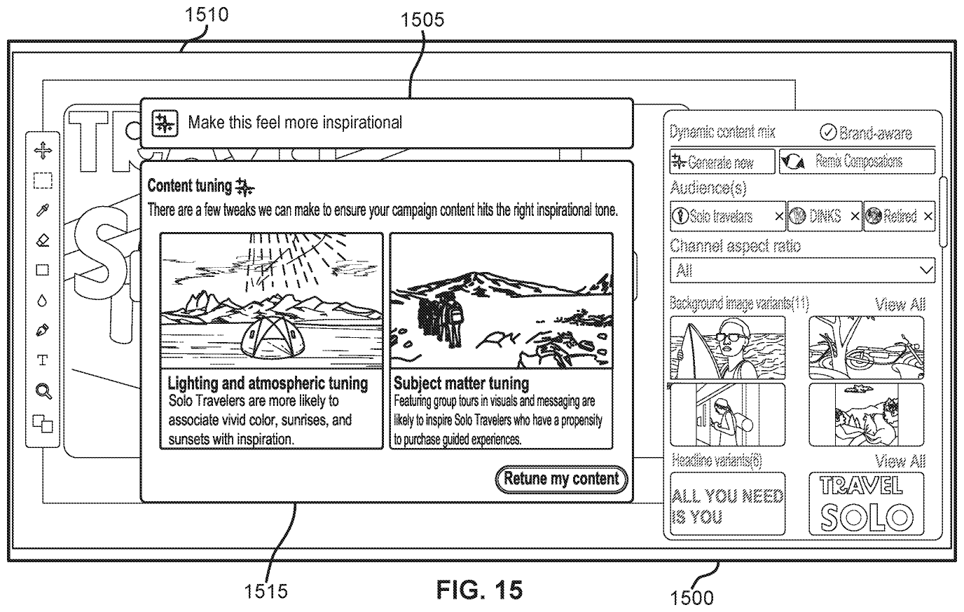

FIG. 14 shows an example of a user interface 1400 for an image according to aspects of the present disclosure. User interface 1400 is an example of, or includes aspects of, the corresponding element described with reference to FIGS. 2, 7-13, and 15-20. In one aspect, user interface 1400 includes prompt element 1405 and fifth content provider context element 1410. Prompt element 1405 is an example of, or includes aspects of, the corresponding element described with reference to FIGS. 8, 9, 11, 12, 15, 17, and 18. Fifth content provider context element 1410 is an example of, or includes aspects of, the corresponding element described with reference to FIGS. 15-18.

FIG. 15 shows an example of a user interface 1500 for image modification according to aspects of the present disclosure. User interface 1500 is an example of, or includes aspects of, the corresponding element described with reference to FIGS. 2, 7-14, and 16-20. In one aspect, user interface 1500 includes prompt element 1505, fifth content provider context element 1510, and sixth content provider context element 1515. Prompt element 1505 is an example of, or includes aspects of, the corresponding element described with reference to FIGS. 8, 9, 11, 12, 14, 17, and 18. Fifth content provider context element 1510 is an example of, or includes aspects of, the corresponding element described with reference to FIGS. 14, and 16-18.

FIG. 16 shows an example of a user interface 1600 for a modified image according to aspects of the present disclosure. User interface 1600 is an example of, or includes aspects of, the corresponding element described with reference to FIGS. 2, 7-15, and 17-20. In one aspect, user interface 1600 includes fifth content provider context element 1605. Fifth content provider context element 1605 is an example of, or includes aspects of, the corresponding element described with reference to FIGS. 14, 15, 17, and 18.

Referring to FIGS. 13-16, a content provider uses a content generation system (such as the content generation system described with reference to FIGS. 1 and 4) to generate images for a content distribution campaign project. For example, as shown in FIG. 13, user interface 1300 displays third content provider context element 1305 including a representation of a content distribution campaign. As shown in FIG. 14, user interface 1400 displays prompt element 1405 on top of a backgrounded fifth content provider context element 1410, where fifth content provider context element 1410 is provided in response to a content provider selection of the “View composed examples” button of third content provider context element 1305. Fifth content provider context element 1410 includes a representation of an image generated for the content distribution campaign project and interface elements for modifying the image or selecting another image to modify.

As shown in FIG. 15, a content provider provides a content provider input “Make this feel more inspirational” to prompt element 1505 displayed by user interface 1500 above the backgrounded fifth content provider context element 1510. User interface 1500 displays sixth content provider context element 1515 including a representation of content relating to suggested different images based on the content provider input and the content provider context. Referring to FIGS. 15 and 16, user interface 1600 displays a modified fifth content provider context element 1605 including an image suggested by sixth content provider context element 1515.

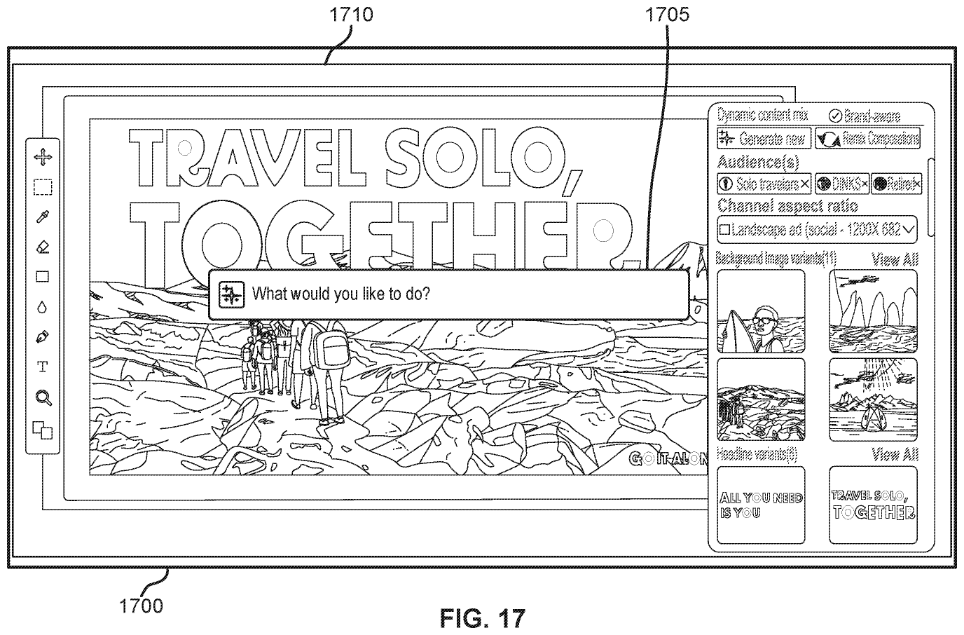

FIG. 17 shows an example of a user interface 1700 for an image according to aspects of the present disclosure. User interface 1700 is an example of, or includes aspects of, the corresponding element described with reference to FIGS. 2, 7-16, and 18-20. In one aspect, user interface 1700 includes prompt element 1705 and fifth content provider context element 1710. Prompt element 1705 is an example of, or includes aspects of, the corresponding element described with reference to FIGS. 8, 9, 11, 12, 14, 15, and 18. Fifth content provider context element 1710 is an example of, or includes aspects of, the corresponding element described with reference to FIGS. 14-16, and 18.

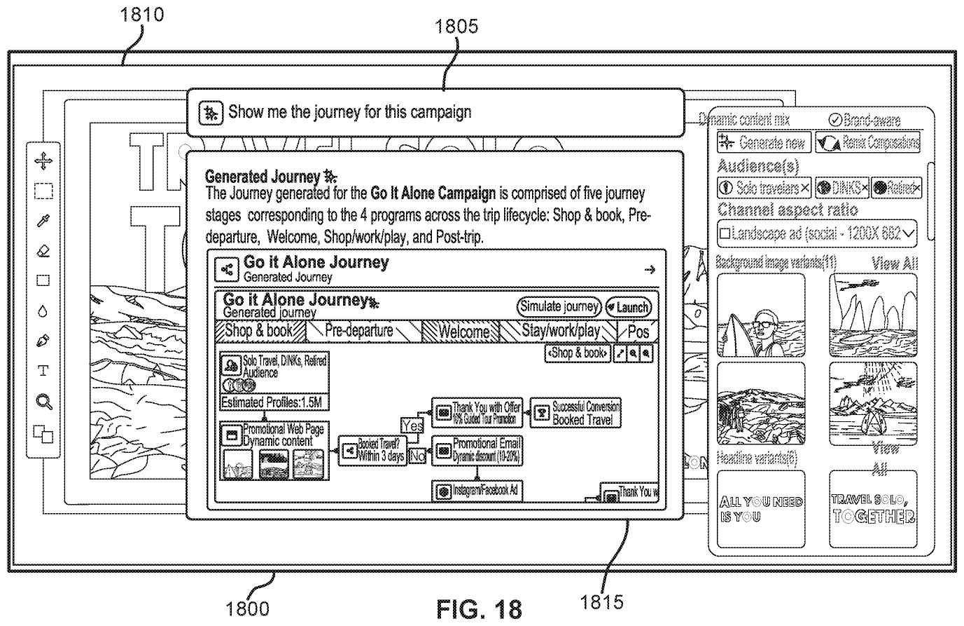

FIG. 18 shows an example of a user interface 1800 for user journey generation according to aspects of the present disclosure. User interface 1800 is an example of, or includes aspects of, the corresponding element described with reference to FIGS. 2, 7-17, 19, and 20. In one aspect, user interface 1800 includes prompt element 1805, fifth content provider context element 1810, and seventh content provider context element 1815. Prompt element 1805 is an example of, or includes aspects of, the corresponding element described with reference to FIGS. 8, 9, 11, 12, 14, 15, and 17. Fifth content provider context element 1810 is an example of, or includes aspects of, the corresponding element described with reference to FIGS. 14-17.

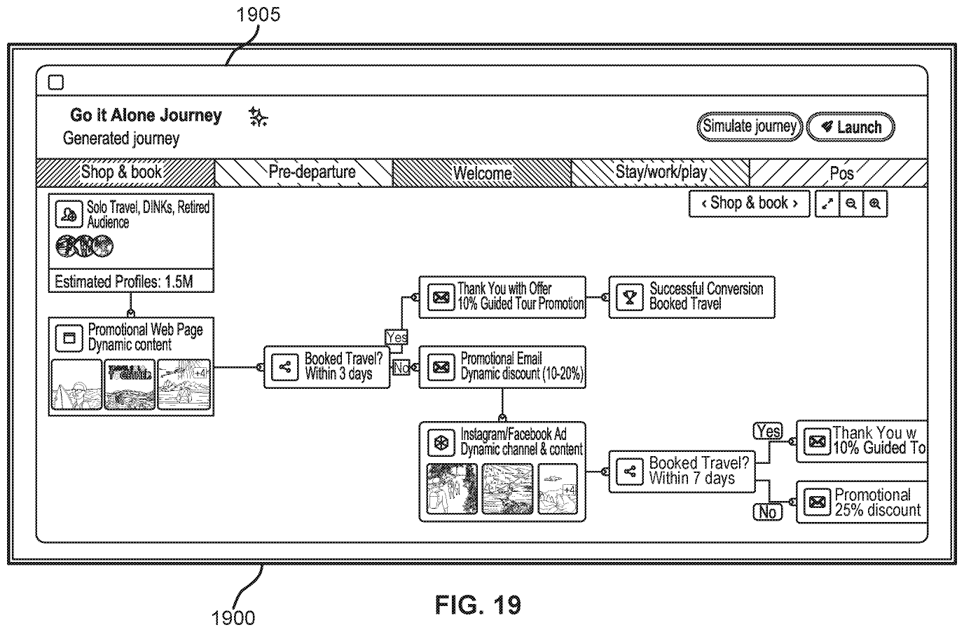

FIG. 19 shows an example of a user interface 1900 for a user journey according to aspects of the present disclosure. User interface 1900 is an example of, or includes aspects of, the corresponding element described with reference to FIGS. 2, 7-18, and 20. In one aspect, user interface 1900 includes eighth content provider context element 1905.

Referring to FIGS. 16-19, a content provider uses a content generation system (such as the content generation system described with reference to FIGS. 1 and 4) to generate a user journey for a content distribution campaign based on an image. For example, as shown in FIG. 16, user interface 1600 displays fifth content provider context element 1605 including an image. As shown in FIG. 17, user interface 1700 displays prompt element 1705 on top of a backgrounded fifth content provider context element 1710.

As shown in FIG. 18, a content provider provides a content provider input “Show me the journey for this campaign” to prompt element 1805 displayed by user interface 1800 above the backgrounded fifth content provider context element 1810. User interface 1800 displays seventh content provider context element 1815 including a representation of a user journey based on the content provider input and the content provider context. Referring to FIGS. 18 and 19, eighth content provider context element 1905 of user interface 1900 displays an enlarged representation of the user journey represented in seventh content provider context element 1815.

FIG. 20 shows an example of a user interface 2000 for a modification of an active content distribution campaign according to aspects of the present disclosure. User interface 2000 is an example of, or includes aspects of, the corresponding element described with reference to FIGS. 2, and 7-19. In one aspect, user interface 2000 includes ninth content provider context element 2005.

Referring to FIG. 20, user interface 2000 displays ninth content provider context element 2005 including suggested modifications to an active content distribution campaign in response to detecting an emerging trend corresponding to the active content distribution campaign.

### Training

FIG. 21 shows an example of a method 2100 for training a machine learning model according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

At operation 2105, the system obtains training data. In some cases, the operations of this step refer to, or are performed by, a training component as described with reference to FIG. 2. In some cases, the training data includes a training prompt and ground-truth content. In some cases, the training prompt is a prompt as described herein, and the ground-truth content is content as described herein. In some cases, the training component obtains the training data from a database (such as the database described with reference to FIG. 1) or from another data source (such as the Internet). In some cases, the training data includes a set of training prompts and a corresponding set of ground-truth content.

At operation 2110, the system trains a machine learning model to generate content using the training data. In some cases, the operations of this step refer to, or are performed by, a training component as described with reference to FIG. 2.

For example, in some cases, the training component provides one or more training prompts to a machine learning model (such as the machine learning model described with reference to FIGS. 2 and 4). In some cases, the machine learning model generates content based on the one or more training prompts as described with reference to FIG. 6. In some cases, the training component compares the content to one or more of the ground-truth content corresponding to the one or more training prompts to determine a loss function.

The term “loss function” refers to a function that impacts how a machine learning model is trained in a supervised learning model. For example, during each training iteration, the output of the machine learning model is compared to the known annotation information in the training data. The loss function provides a value (a “loss”) for how close the predicted annotation data is to the actual annotation data. After computing the loss, the parameters of the model are updated accordingly and a new set of predictions are made during the next iteration.

Supervised learning is one of three basic machine learning paradigms, alongside unsupervised learning and reinforcement learning. Supervised learning is a machine learning technique based on learning a function that maps an input to an output based on example input-output pairs. Supervised learning generates a function for predicting labeled data based on labeled training data consisting of a set of training examples. In some cases, each example is a pair consisting of an input object (typically a vector) and a desired output value (i.e., a single value, or an output vector). In some cases, a supervised learning algorithm analyzes the training data and produces the inferred function, which is used for mapping new examples. In some cases, the learning results in a function that correctly determines the class labels for unseen instances. In other words, the learning algorithm generalizes from the training data to unseen examples.

In some cases, the training component trains the machine learning model by updating the machine learning parameters of the machine learning model according to the loss function.

The description and drawings described herein represent example configurations and do not represent all the implementations within the scope of the claims. For example, the operations and steps can be rearranged, combined, or otherwise modified. Also, in some cases, structures and devices are represented in the form of block diagrams to represent the relationship between components and avoid obscuring the described concepts. In some cases, similar components or features have the same name but have different reference numbers corresponding to different figures.

Some modifications to the disclosure are readily apparent to those skilled in the art, and the principles defined herein can be applied to other variations without departing from the scope of the disclosure. Thus, the disclosure is not limited to the examples and designs described herein, but is to be accorded the broadest scope consistent with the principles and novel features disclosed herein.

In some embodiments, the described methods are implemented or performed by devices that include a general-purpose processor, a digital signal processor (DSP), an application specific integrated circuit (ASIC), a field programmable gate array (FPGA) or other programmable logic device, discrete gate or transistor logic, discrete hardware components, or any combination thereof. In some embodiments, a general-purpose processor is a microprocessor, a conventional processor, controller, microcontroller, or state machine. In some embodiments, a processor is implemented as a combination of computing devices (e.g., a combination of a DSP and a microprocessor, multiple microprocessors, one or more microprocessors in conjunction with a DSP core, or any other such configuration). Thus, in some embodiments, the functions described herein are implemented in hardware or software and are executed by a processor, firmware, or any combination thereof. In some embodiments, if implemented in software executed by a processor, the functions are stored in the form of instructions or code on a computer-readable medium.

Computer-readable media includes both non-transitory computer storage media and communication media including any medium that facilitates transfer of code or data. In some embodiments, a non-transitory storage medium is any available medium that is accessible by a computer. For example, in some cases, non-transitory computer-readable media comprise random access memory (RAM), read-only memory (ROM), electrically erasable programmable read-only memory (EEPROM), compact disk (CD) or other optical disk storage, magnetic disk storage, or any other non-transitory medium for carrying or storing data or code.

Also, in some embodiments, connecting components are properly termed computer-readable media. For example, if code or data is transmitted from a website, server, or other remote source using a coaxial cable, fiber optic cable, twisted pair, digital subscriber line (DSL), or wireless technology such as infrared, radio, or microwave signals, then the coaxial cable, fiber optic cable, twisted pair, DSL, or wireless technology are included in the definition of medium. Combinations of media are also included within the scope of computer-readable media.

In this disclosure and the following claims, the word “or” indicates an inclusive list such that, for example, the list of X, Y, or Z means X or Y or Z or XY or XZ or YZ or XYZ. Also the phrase “based on” is not used to represent a closed set of conditions. For example, a step that is described as “based on condition A” can be based on both condition A and condition B. In other words, the phrase “based on” shall be construed to mean “based at least in part on.” Also, the words “a” or “an” indicate “at least one.”

What is claimed is:

1. A method for content generation, comprising:
obtaining, by a user experience platform, a content provider context for the user experience platform, wherein the content provider context includes profile information for a content provider and an interaction history of the content provider;
obtaining, by the user experience platform, a prompt based on the content provider context; and
generating content for a project within the user experience platform based on the prompt using a machine learning model.

2. The method of claim 1, further comprising:
displaying, by a user interface, a prompt element based on the interaction history; and
receiving, by the user interface, a content provider input via the prompt element, wherein the prompt is based on the content provider input.

3. The method of claim 1, further comprising:
generating, by the user experience platform, the prompt based on the content provider context.

4. The method of claim 1, wherein:
the content provider context includes information in multiple modalities including a text modality and an image modality, wherein the content is generated based on the information in the multiple modalities.

5. The method of claim 1, wherein:
the content provider context comprises a user journey, analytics context, an audience segmentation context, a campaign generation context, or any combination thereof.

6. The method of claim 1, wherein:
the content provider context includes structured information representing a user journey, a campaign brief, or a campaign program.

7. The method of claim 1, further comprising:
providing, by the user experience platform, a recommendation to the content provider for an interaction with the user experience platform, wherein the recommendation is based on the content.

8. The method of claim 1, further comprising:
receiving, by the machine learning model, a request from the content provider to generate the content, wherein the content is generated in response to the request.

9. The method of claim 1, further comprising:
receiving, by a training component, feedback from the content provider based on the content; and
updating, by the training component, the machine learning model based on the feedback.

10. The method of claim 1, wherein:
the machine learning model is trained based on a public corpus of natural language documents and fine-tuned based on data from the user experience platform.

11. A non-transitory computer readable medium storing code for content generation, the code comprising instructions executable by a processor to:
obtain a content provider context for a user experience platform, wherein the content provider context includes profile information for a content provider and an interaction history of the content provider;
obtain a prompt based on the content provider context; and
generate content for a project within the user experience platform based on the prompt using a machine learning model.

12. The non-transitory computer readable medium of claim 11, the code further comprising instructions executable by the processor to:
display a prompt element based on the interaction history; and
receive a content provider input via the prompt element, wherein the prompt is based on the content provider input.

13. The non-transitory computer readable medium of claim 11, the code further comprising instructions executable by the processor to:
generate the prompt based on the content provider context.

14. The non-transitory computer readable medium of claim 11, wherein:
the content provider context includes information in multiple modalities including a text modality and an image modality, wherein the content is generated based on the information in the multiple modalities.

15. The non-transitory computer readable medium of claim 11, wherein:
the content provider context comprises a user journey, analytics context, an audience segmentation context, a campaign generation context, or any combination thereof.

16. The non-transitory computer readable medium of claim 11, wherein:
the content provider context includes structured information representing a user journey, a campaign brief, or a campaign program.

17. The non-transitory computer readable medium of claim 11, the code further comprising instructions executable by the processor to:
provide a recommendation to the content provider for an interaction with the user experience platform, wherein the recommendation is based on the content.

18. The non-transitory computer readable medium of claim 11, the code further comprising instructions executable by the processor to:
receive a request from the content provider to generate the content, wherein the content is generated in response to the request.

19. The non-transitory computer readable medium of claim 11, wherein:
the machine learning model is trained based on a public corpus of natural language documents and fine-tuned based on data from the user experience platform.

20. An apparatus for content generation, comprising:
at least one processor;
at least one memory storing instructions executable by the at least one processor;
a user experience platform configured to obtain a prompt based on a content provider context for the user experience platform, wherein the content provider context includes profile information for a content provider and an interaction history of the content provider; and
a machine learning model including machine learning model parameters stored in the at least one memory and trained to generate content for a project within the user experience platform based on the prompt.
